(19) United States
(12) Patent Application Publication
(10) Pub. No.: US 2016/0203997 A1
(43) Pub. Date: Jul. 14, 2016

(54) SUBSTRATE PROCESSING METHOD

(71) Applicant: SCREEN Semiconductor Solutions Co., Ltd., Kyoto (JP)

(72) Inventors: Tadashi Miyagi, Kyoto (JP); Masashi Kanaoka, Kyoto (JP); Tetsuya Hamada, Kyoto (JP); Kazuhito Shigemori, Kyoto (JP); Shuichi Yasuda, Kyoto (JP)

(21) Appl. No.: 15/078,772

(22) Filed: Mar. 23, 2016

Related U.S. Application Data
(63) Continuation of application No. 13/284,603, filed on Oct. 28, 2011.
Application No. 13/284,603 is a division of application No. 11/897,965, filed on Aug. 31, 2007, now abandoned.

(30) Foreign Application Priority Data
Aug. 31, 2006 (JP) 2006-235085

(51) Int. Cl. H01L 21/3105; H01L 21/677; H01L 21/67; H01L 21/027

(52) U.S. Cl. CPC H01L 21/31058; H01L 21/0276; H01L 21/67706; H01L 21/67259

(57) ABSTRACT

A substrate processing method includes forming a first film on the upper surface of the substrate and supplying a first removal liquid to a peripheral edge of said first film to remove a first annular region at the peripheral edge. The method also includes correcting a relative positional relationship between the substrate and a first removal nozzle, forming a second film so as to cover the first film, and supplying a second removal liquid to a peripheral edge of said second film to remove a second annular region at the peripheral edge. The method also includes correcting a relative positional relationship between the substrate and a second removal nozzle so that said second annular region at the peripheral edge of said second film is removed in a predetermined second constant width and carrying the substrate into each of a first and second film formation units by a carry-in device.

### CROSS-REFERENCES TO RELATED APPLICATIONS

This application is a continuation of U.S. patent application Ser. No. 13/284,603, filed Oct. 28, 2011, which is a divisional of U.S. patent application Ser. No. 11/897,965, filed Aug. 31, 2007, which claims priority to Japanese Patent Application 2006-235085, filed Aug. 31, 2006, and the disclosures of these applications are incorporated by reference in their entireties herein for all purposes.

### BACKGROUND OF THE INVENTION

The present invention relates to a substrate processing apparatus that subjects substrates to processing.

Substrate processing apparatuses are used to subject various types of substrates such as semiconductor substrates, substrates for liquid crystal displays, plasma displays, optical disks, magnetic disks, magneto-optical disks, and photomasks, and other substrates to various types of processing.

Such a substrate processing apparatus generally subjects a single substrate to a plurality of different types of processing successively. The substrate processing apparatus as described in JP 2003-324139 A comprises an indexer block, an anti-reflection film processing block, a resist film processing block, a development processing block, and an interface block. An exposure device is arranged adjacent to the interface block as an external device separate from the substrate processing apparatus.

In the above-mentioned substrate processing apparatus, a substrate carried out of the indexer block is transported to the exposure device through the interface block after being subjected to anti-reflection film formation and resist film coating processing in the anti-reflection film processing block and the resist film processing block. After the resist film on the substrate is subjected to exposure processing in the exposure device, the substrate is transported to the development processing block through the interface block. After the resist film on the substrate is subjected to development processing to form a resist pattern thereon in the development processing block, the substrate is transported to the indexer block.

With recent increases in density and integration of devices, making finer resist patterns has become an important problem. Conventional exposure devices have generally performed exposure processing by reduction-projecting a reticle pattern on a substrate through a projection lens. With such conventional exposure devices, however, the line width of an exposure pattern is determined by the wavelength of a light source of the exposure device. Therefore, making finer resist patterns has had a limitation.

Therefore, a liquid immersion method is suggested as a projection exposure method allowing for finer exposure patterns (see, e.g., WO99/49504 pamphlet). In the projection exposure device according to the WO99/49504 pamphlet, an area between a projection optical system and a substrate is filled with a liquid, resulting in a shorter wavelength of exposure light on a main surface of the substrate. This allows for finer exposure patterns.

In the projection exposure device according to the WO99/49504 pamphlet, exposure processing is performed with a resist film formed on the substrate and the liquid brought into contact with each other.

When the resist film is brought into contact with the liquid, a component in the resist film is leeched into the liquid. In this case, the photosensitive performance of the resist film is degraded. In order to prevent the component in the resist film from leeching into the liquid, therefore, a cover film (hereinafter referred to as a resist cover film) is formed so as to cover the resist film.

On the substrate before the exposure processing, an anti-reflection film for reducing a standing wave or halation generated during the exposure processing is also formed in addition to the resist film and the resist cover film.

A film formed at a peripheral edge of the substrate may, in some cases, be changed into particles by being stripped due to mechanical contact at the time of transporting the substrate. Consequently, it is preferable to remove the film formed at the peripheral edge of the substrate.

Therefore, JP 7-326568 A discloses, for example, a spin coating device comprising a thin film removal device for discharging a removal liquid from a needle-shaped nozzle into a peripheral edge of a substrate after formation of a thin film and dissolving and removing the unnecessary thin film at the peripheral edge of the substrate.

In recent years, it has been needed to further refine the exposure pattern as well as to increase the number of chips obtained from one wafer. Consequently, it is preferable that a removal region of a film formed at the peripheral edge of the substrate is made as small as possible.

When a plurality of films are formed on the surface of the substrate, a removal region corresponding to each of the films must be accurately set. For example, a removal region of the resist cover film is made smaller than a removal region of the resist film. The reason for this is that the resist cover film must completely cover the resist film even at the peripheral edge of the substrate in order to prevent the component in the resist film from being eluded.

In the above-mentioned spin coating device disclosed in JP 7-326568 A, however, it is difficult to accurately remove the film at the peripheral edge of the substrate with high precision as required in recent years. For example, the resist film provided in a chip formation region on a wafer may be erroneously removed, and the resist cover film may be removed in a resist film formation region to expose a part of the resist film.

### SUMMARY OF THE INVENTION

An object of the present invention is to provide a substrate processing apparatus capable of accurately removing a film at a peripheral edge of a substrate with high precision.

According to an embodiment of the present invention, a substrate processing apparatus arranged adjacent to an exposure device is provided. The substrate processing apparatus includes a processing section configured to subject a substrate to processing. The processing section includes a film formation unit configured to form a film on a surface of the substrate before exposure processing by the exposure device. The film formation unit includes a substrate holding device configured to hold the substrate in a substantially horizontally orientation and a rotation driving device configured to rotate the substrate held by the substrate holding device around an axis perpendicular to the substrate. The film formation unit also includes a film formation device configured to supply a coating liquid to the substrate rotated by the rotation driving device to form a film and a removal device configured to remove an annular region at a peripheral edge of the film formed on the substrate rotated by the rotation driving device. The film formation unit further includes a position correction device configured to correct a position at which the removal device removes the peripheral edge of the film. The substrate processing apparatus also includes an interface provided adjacent to one end of the processing section and configured to transfer and receive the substrate between the processing section and the exposure device.

(1) A substrate processing apparatus according to an aspect of the present invention is a substrate processing apparatus that is arranged adjacent to an exposure device, comprising a processing section that subjects a substrate to processing, and an interface provided adjacent to one end of the processing section for transferring and receiving the substrate between the processing section and the exposure device, the processing section including a film formation unit that forms a film on a surface of the substrate before exposure processing by the exposure device, the film formation unit comprising a substrate holding device that holds the substrate substantially horizontally, a rotation driving device that rotates the substrate held by the substrate holding device around an axis perpendicular to the substrate, a film formation device that supplies a coating liquid to the substrate rotated by the rotation driving device to form a film, a removal device that removes an annular region at a peripheral edge of the film formed on the substrate rotated by the rotation driving device, and a position correction device that corrects the position where the removal device removes the peripheral edge of the film.

The substrate processing apparatus according to the aspect of the present invention is arranged adjacent to the exposure device. In the substrate processing apparatus, the processing section subjects the substrate to the predetermined processing, and the interface provided adjacent to the one end of the processing section receives and transfers the substrate between the processing section and the exposure device.

Before the exposure processing by the exposure device, in the film formation unit, the film formation device supplies the coating liquid to the substrate rotated by the rotation driving device so that the film is formed on the surface of the substrate.

Furthermore, in the film formation unit, the removal device removes the annular region at the peripheral edge of the film formed on the substrate rotated by the rotation driving device. At this time, the position correction device corrects the position where the removal device removes the peripheral edge of the film. This allows the annular region at the peripheral edge of the film formed on the surface of the substrate to be accurately removed with high precision.

Thus, the region to be removed at the peripheral edge of the film on the substrate can be made sufficiently small, which allows the number of chips obtained from the one substrate to be increased.

In such a way, the peripheral edge of the film on the substrate is removed, which prevents particles caused by mechanical contact between the holder in the transport device and the film on the substrate from being generated at the time of transporting the substrate. As a result, processing defects in the substrate due to the effect of the particles are prevented.

(2) The film formation unit may comprise a first film formation unit that forms a lower layer film on the substrate before the exposure processing by the exposure device and removes a first annular region at a peripheral edge of the lower layer film, a second film formation unit that forms a protective film so as to cover the lower layer film before the exposure processing by the exposure device and removes a second annular region at a peripheral edge of the photosensitive film, and a third film formation unit that forms a protective film so as to cover the lower layer film and the photosensitive film before the exposure processing by the exposure device and removes a third annular region at a peripheral edge of the protective film, each of the first, second, and third film formation units may include the substrate holding device, the rotation driving device, the film formation device, the removal device, and the position correction device, the third annular region may be made smaller than the second annular region, and the first annular region may be made smaller than the second and third annular regions.

In this case, in the film formation unit, before the exposure processing by the exposure device, the film formation device in the first film formation unit forms the lower layer film on the substrate, and the removal device removes the first annular region at the peripheral edge of the lower layer film. At this time, the position correction device corrects the position where the removal device removes the lower layer film.

Before the exposure processing by the exposure device, the film formation device in the second film formation unit forms the photosensitive film so as to cover the lower layer film, and the removal device removes the second annular region at the peripheral edge of the photosensitive film. At this time, the position correction device corrects the position where the removal device removes the photosensitive film.

Furthermore, before the exposure processing by the exposure device, the film formation device in the third film formation unit forms the protective film so as to cover the lower layer film and the photosensitive film, and the removal device removes the third annular region at the peripheral edge of the protective film. At this time, the position correction device corrects the position where the removal device removes the protective film.

The lower layer film formed on the substrate is more difficult to strip from the substrate, as compared with the photosensitive film and the protective film. Consequently, the first annular region to be removed in the lower layer film is made smaller than the second and third annular regions to be respectively removed in the photosensitive film and the protective film, so that the photosensitive film and the protective film are not formed on the surface of the substrate. Therefore, the stripping of the film from the surface of the substrate is reduced.

Furthermore, the surface of the photosensitive film can be completely covered with the protective film by making the third annular region to be removed in the protective film smaller than the second annular region to be removed in the photosensitive film. This can prevent the photosensitive film from being leeched into the liquid during the exposure processing.

(3) The lower layer film may include an anti-reflection film. In this case, the anti-reflection film is formed on the substrate, which allows a standing wave or halation generated during the exposure processing to be reduced.

(4) The lower layer film may include an organic film formed on the substrate and an oxide film formed on the organic film. In this case, the photosensitive film is formed on the organic film and the oxide film, which prevents pattern collapse of the photosensitive film on the substrate that has been subjected to the exposure processing and the development processing.

(5) The position correction device may correct the position of the substrate held by the substrate holding device such that the center of the substrate coincides with the rotation center of the substrate by the rotation driving device. In this case, in the film formation unit, the position correction device corrects the position of the substrate held substantially horizontally by the substrate holding device such that the center of the substrate coincides with the rotation center of the substrate by the rotation driving device. This prevents the center of the substrate from being eccentric from the rotation center when the peripheral edge of the film on the substrate is removed, which allows the annular region at the peripheral edge of the film formed on the surface of the substrate to be accurately removed with high precision.

(6) The position correction device may include a plurality of abutting members that abut against outer edges of the substrate to correct the position of the substrate. In this case, the abutting members abut against the outer edges of the substrate, and press the substrate in a substantially horizontal direction, to correct the position of the substrate. Even in a case where the organic film is formed on the substrate, therefore, the abutting members can reliably correct the position of the substrate without damaging the organic film on the substrate.

(7) The plurality of abutting members may be respectively arranged at positions symmetrical with the rotation center of the substrate used as a basis and move at equal speeds toward the rotation center of the substrate. In this case, the plurality of abutting members move at the equal speeds toward the rotation center of the substrate, to press the substrate such that the center of the substrate coincides with the rotation center of the substrate. This allows the position of the substrate to be quickly and reliably corrected in a simple configuration.

(8) The plurality of abutting members may be arranged so as to extend, inclined obliquely upward outward from the rotation center of the substrate by the rotation driving mechanism, the position correction device may further include a lifting device that holds the plurality of abutting members so as to be movable upward and downward, and the lifting device may raise the plurality of abutting members such that the plurality of abutting members abut against the outer edges of the substrate.

In this case, when the lifting device raises the plurality of abutting members, any one of the plurality of abutting members abuts against the outer edges of the substrate. When the lifting device further raises the plurality of abutting members in this state, it moves in the horizontal direction toward the rotation center of the substrate by the rotation driving device while sliding along the abutting member that abuts against the outer edges of the substrate because the abutting members extend, inclined obliquely upward outward from the rotation center of the substrate.

Thus, the plurality of abutting members abut against the outer edges of the substrate, so that the center of the substrate and the rotation center of the substrate by the rotation driving device coincide with each other. This allows the position of the substrate to be quickly and reliably corrected in a simple configuration.

(9) The position correction device may include a supporting member that supports a reverse surface of the substrate and moves in a substantially horizontal direction to correct the position of the substrate. In this case, the supporting member moves in the substantially horizontal direction so that the position of the substrate is corrected with the reverse surface of the substrate supported by the supporting member. Even in a case where the organic film is formed on the substrate, therefore, the supporting member can reliably correct the position of the substrate without damaging the organic film on the substrate.

(10) The substrate processing apparatus may further comprise a substrate position detector that detects the position of the substrate relative to the substrate holding device, and a control device that controls the position correction device on the basis of an output signal of the substrate position detector. In this case, the control device accurately recognizes the position of the substrate relative to the substrate holding device. The control device controls the position correction device on the basis of the recognition, so that the position of the substrate is accurately corrected.

(11) The position correction device may include an edge detector that detects the position of an edge of the substrate rotated by the rotation driving device, and a removal device moving mechanism that moves the removal device such that the relative position between the removal device and the center of the substrate is held on the basis of the position of the edge of the substrate detected by the edge detector. In this case, the edge detector detects the position of the edge of the substrate rotated by the rotation driving device. The removal device moving mechanism moves the removal device such that the relative position between the removal device and the center of the substrate is held on the basis of the detected position of the edge of the substrate.

Thus, the relative position between the removal device and the center of the substrate is held even in a case where the center of the substrate and the rotation center of the substrate by the rotation driving device are shifted from each other when the annular region at the peripheral edge of the film formed on the substrate is removed. This allows the annular region at the peripheral edge of the film to be accurately removed with high precision.

Furthermore, the annular region at the peripheral edge of the film removed by the removal device can be adjusted with high precision. This allows the annular region at the peripheral edge of the film formed on the substrate to be selectively and accurately removed. This prevents a portion of the film formed on the substrate, which should not be removed, from being unnecessary removed.

(12) The position correction device may include an edge detector that detects the position of an edge of the substrate rotated by the rotation driving device, and a holding device moving mechanism that moves the substrate holding device such that the relative position between the removal device and the center of the substrate is held on the basis of the position of the edge of the substrate detected by the edge detector. In this case, the edge detector detects the position of the edge of the substrate rotated by the rotation driving device. The holding device moving mechanism moves the substrate holding device such that the relative position between the removal device and the center of the substrate is held on the basis of the detected position of the edge of the substrate.

Thus, the relative position between the removal device and the center of the substrate is held even in a case where the center of the substrate and the rotation center of the substrate by the rotation driving device are shifted from each other when the peripheral edge of the film on the substrate is removed, which allows the annular region at the peripheral edge of the film to be accurately removed with high precision.

Furthermore, the annular region at the peripheral edge of the film removed by the removal device can be accurately adjusted with high precision. This prevents a portion of the film formed on the substrate, which should not be removed, from being unnecessary removed.

(13) The substrate processing apparatus may further comprise a carry-in device that carries the substrate into the film formation unit, and the position correction device may include a carry-in position detector that detects the position of the carry-in device in a case where the carry-in device carries the substrate into the film formation unit, and a position adjustment device that adjusts the position of the carry-in device on the basis of the position detected by the carry-in position detector.

In this case, the carry-in position detector detects the position of the carry-in device when the carry-in device carries the substrate into the film formation unit, and the position adjustment device adjusts the position of the carry-in device on the basis of the detected position. This causes the position of the substrate placed on the substrate holding device to be corrected. Even in a case where the organic film is formed on the substrate, therefore, the abutting members can reliably correct the position of the substrate without damaging the organic film on the substrate.

(14) The interface may include a transport device that transports the substrate between the processing section and the exposure device, the transport device may include first and second holders that hold the substrate, the first holder may hold, when the substrate before the exposure processing is transported, the substrate, and the second holder may hold, when the substrate after the exposure processing is transported, the substrate.

In this case, even if the liquid adheres to the substrate during the exposure processing, the second holder is used for transporting the substrate after the exposure processing, and the first holder is used for transporting the substrate before the exposure processing, so that the liquid can be prevented from adhering to the first holder. Thus, the liquid can be prevented from adhering to the substrate before the exposure processing. This can reliably prevent particles and the like in an atmosphere from adhering to the substrate before the exposure processing.

(15) The second holder may be provided below the first holder. In this case, even if the liquid drops from the second holder and the substrate held thereby, the liquid does not adhere to the first holder and the substrate held thereby. This can reliably prevent the particles and the like from adhering to the substrate before the exposure processing.

Other features, elements, characteristics, and advantages of the present invention will become more apparent from the following description of preferred embodiments of the present invention with reference to the attached drawings.

### BRIEF DESCRIPTION OF THE DRAWINGS

FIG. 1 is a schematic plan view of a substrate processing apparatus according to a first embodiment;

FIG. 2 is a side view of the substrate processing apparatus shown in FIG. 1 as viewed from a +X direction;

FIG. 3 is a side view of the substrate processing apparatus shown in FIG. 1 as viewed from a −X direction;

FIG. 4 is a diagram for explaining the configuration of a coating unit;

FIG. 5 is a top view showing the operations of a guide arm and a substrate;

FIG. 6 is a diagram showing the procedure for forming an anti-reflection film, a resist film, and a resist cover film on a surface of a substrate and a removal region of each of the films;

FIG. 7 is a diagram for explaining another example of the configuration of a coating unit;

FIG. 8 is a flowchart showing an example of control of a coating unit by a local controller;

FIG. 9 is a diagram for explaining still another example of the configuration of a coating unit;

FIG. 10 is a diagram for explaining an operation for raising and lowering four support pins and a processing cup in the coating unit shown in FIG. 9;

FIG. 11 is a diagram for explaining an operation for raising and lowering four support pins and a processing cup in the coating unit shown in FIG. 9;

FIG. 12 is a diagram for explaining still another example of the configuration of a coating unit;

FIG. 13 is a diagram for explaining still another example of the configuration of a coating unit;

FIG. 14 is a diagram for explaining still another example of the configuration of a coating unit;

FIG. 15 is a diagram for explaining the operation of a hand shown in FIG. 14 at the time of carrying a substrate into a coating unit;

FIG. 16 is a schematic plan view of a substrate processing apparatus according to a second embodiment;

FIG. 17 is a side view of the substrate processing apparatus shown in FIG. 16 as viewed from a +X direction;

FIG. 18 is a side view of the substrate processing apparatus shown in FIG. 16 as viewed from a −X direction; and

FIG. 19 is a diagram showing the procedure for forming an organic lower layer film, an oxide film, a resist film, and a resist cover film on a surface of a substrate and a removal region of each of the films.

### DETAILED DESCRIPTION OF SPECIFIC EMBODIMENTS

A substrate processing apparatus according to an embodiment of the present invention will be described with reference to the drawings. In the following description, a substrate refers to a semiconductor substrate, a substrate for a liquid crystal display, a substrate for a plasma display, a glass substrate for a photomask, a substrate for an optical disk, a substrate for a magnetic disk, a substrate for a magneto-optical disk, a substrate for a photomask, or the like, and the substrate contains silicon (Si).

The following drawings are accompanied by arrows that respectively indicate X, Y, and Z directions perpendicular to one another for clarity of a positional relationship. The X and Y directions are perpendicular to each other within a horizontal plane, and the Z direction corresponds to the vertical direction. In each of the directions, the direction of the arrow is defined as a + direction, and the opposite direction is defined as a − direction. A rotation direction centered around the Z direction is defined as a θ direction.

### (1) Configuration of Substrate Processing Apparatus

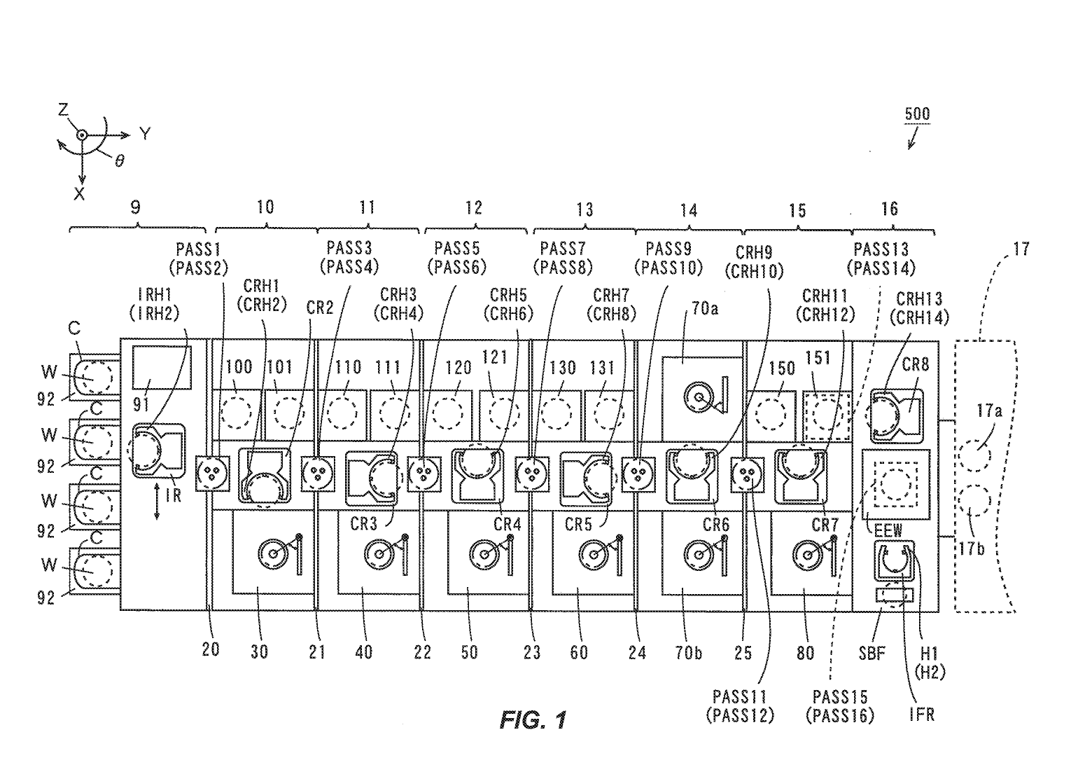

A substrate processing apparatus according to a first embodiment will be now described with reference to the drawings. FIG. 1 is a schematic plan view of the substrate processing apparatus according to the first embodiment. As shown in FIG. 1, a substrate processing apparatus 500 according to the first embodiment comprises an indexer block 9, an anti-reflection film processing block 10, a resist film processing block 11, a development processing block 12, a resist cover film processing block 13, a resist cover film removal block 14, a cleaning/drying processing block 15, and an interface block 16. In the substrate processing apparatus 500, the blocks are arranged side by side in the foregoing order.

An exposure device 17 is arranged adjacent to the interface block 16 in the substrate processing apparatus 500. The exposure device 17 subjects a substrate W to exposure processing by means of a liquid immersion method.

The indexer block 9 includes a main controller (controller) 91 for controlling the operation of each of the blocks, a plurality of carrier platforms 92, and an indexer robot IR. The indexer robot IR has a vertical stack of hands IRH1 and IRH2 for receiving and transferring the substrates W. The anti-reflection film processing block 10 includes thermal processing groups 100 and 101 for anti-reflection film, a coating processing group 30 for anti-reflection film, and a second central robot CR2. The coating processing group 30 is provided opposite to the thermal processing groups 100 and 101 with the second central robot CR2 sandwiched therebetween. The second central robot CR2 has hands CRH1 and CRH2 provided one above the other for receiving and transferring the substrates W.

A partition wall 20 is provided between the indexer block 9 and the anti-reflection film processing block 10 for shielding an atmosphere. The partition wall 20 has substrate platforms PASS1 and PASS2 provided in close proximity one above the other for receiving and transferring the substrates W between the indexer block 9 and the anti-reflection film processing block 10. The upper substrate platform PASS1 is used in transporting the substrates W from the indexer block 9 to the anti-reflection film processing block 10, and the lower substrate platform PASS2 is used in transporting the substrates W from the anti-reflection film processing block 10 to the indexer block 9.

Each of the substrate platforms PASS1 and PASS2 is provided with an optical sensor (not shown) for detecting the presence or absence of the substrate W. This allows determination to be made whether or not the substrate W is placed on the substrate platform PASS1 or PASS2. In addition, each of the substrate platforms PASS1 and PASS2 has a plurality of support pins secured thereto. Note that each of substrate platforms PASS3 to PASS16 described later is similarly provided with an optical sensor and support pins.

The resist film processing block 11 includes thermal processing groups 110 and 111 for resist film, a coating processing group 40 for resist film, and a third central robot CR3. The coating processing group 40 is provided opposite to the thermal processing groups 110 and 111 with the third central robot CR3 interposed therebetween. The third central robot CR3 has hands CRH3 and CRH4 provided one above the other for receiving and transferring the substrates W.

A partition wall 21 is provided between the anti-reflection film processing block 10 and the resist film processing block 11 for shielding an atmosphere. The partition wall 21 has substrate platforms PASS3 and PASS4 provided in close proximity one above the other for receiving and transferring the substrates W between the anti-reflection film processing block 10 and the resist film processing block 11. The upper substrate platform PASS3 is used in transporting the substrates W from the anti-reflection film processing block 10 to the resist film processing block 11, and the lower substrate platform PASS4 is used in transporting the substrates W from the resist film processing block 11 to the anti-reflection film processing block 10.

The development processing block 12 includes thermal processing groups 120 and 121 for development, a development processing group 50, and a fourth central robot CR4. The development processing group 50 is provided opposite to the thermal processing groups 120 and 121 with the fourth central robot CR4 interposed therebetween. The fourth central robot CR4 has hands CRH5 and CRH6 provided one above the other for receiving and transferring the substrates W.

A partition wall 22 is provided between the resist film processing block 11 and the development processing block 12 for shielding an atmosphere. The partition wall 22 has substrate platforms PASS5 and PASS6 provided in close proximity one above the other for receiving and transferring the substrates W between the resist film processing block 11 and the development processing block 12. The upper substrate platform PASS5 is used in transporting the substrates W from the resist film processing block 11 to the development processing block 12, and the lower substrate platform PASS6 is used in transporting the substrates W from the development processing block 12 to the resist film processing block 11.

The resist cover film processing block 13 includes thermal processing groups 130 and 131 for resist cover film, a coating processing group 60 for resist cover film, and a fifth central robot CR5. The coating processing group 60 is provided opposite to the thermal processing groups 130 and 131 with the fifth central robot CR5 interposed therebetween. The fifth central robot CR5 has hands CRH7 and CRH8 provided one above the other for receiving and transferring the substrates W.

A partition wall 23 is provided between the development processing block 12 and the resist cover film processing block 13 for shielding an atmosphere. The partition wall 23 has substrate platforms PASS7 and PASS8 provided in close proximity one above the other for receiving and transferring the substrates W between the development processing block 12 and the resist cover film processing block 13. The upper substrate platform PASS7 is used in transporting the substrates W from the development processing block 12 to the resist cover film processing block 13, and the lower substrate platform PASS8 is used in transporting the substrates W from the resist cover film processing block 13 to the development processing block 12.

The resist cover film removal block 14 includes removal processing groups 70a and 70b for resist cover film and a sixth central robot CR6. The removal processing groups 70a and 70b are provided opposite to each other with the sixth central robot CR6 interposed therebetween. The sixth central robot CR6 has hands CRH9 and CRH10 provided one above the other for receiving and transferring the substrates W.

A partition wall 24 is provided between the resist cover film processing block 13 and the resist cover film removal block 14 for shielding an atmosphere. The partition wall 24 has substrate platforms PASS9 and PASS10 provided in close proximity one above the other for receiving and transferring the substrates W between the resist cover film processing block 13 and the resist cover film removal block 14. The upper substrate platform PASS9 is used in transporting the substrates W from the resist cover film processing block 13 to the resist cover film removal block 14, and the lower substrate platform PASS10 is used in transporting the substrates W from the resist cover film removal block 14 to the resist cover film processing block 13.

The cleaning/drying processing block 15 includes thermal processing groups 150 and 151 for post-exposure bake, a cleaning/drying processing group 80, and a seventh central robot CR7. The thermal processing group 151 is adjacent to the interface block 16, and comprises substrate platforms PASS13 and PASS14, as described later. The cleaning/drying processing group 80 is provided opposite to the thermal processing groups 150 and 151 with the seventh central robot CR7 interposed therebetween. The seventh central robot CR7 has hands CRH11 and CRH12 provided one above the other for receiving and transferring the substrates W.

A partition wall 25 is provided between the resist cover film removal block 14 and the cleaning/drying processing block 15 for shielding an atmosphere. The partition wall 25 has substrate platforms PASS11 and PASS12 provided in close proximity one above the other for receiving and transferring the substrates W between the resist cover film removal block 14 and the cleaning/drying processing block 15. The upper substrate platform PASS11 is used in transporting the substrates W from the resist cover film removal block 14 to the cleaning/drying processing block 15, and the lower substrate platform PASS12 is used in transferring the substrates W from the cleaning/drying processing block 15 to the resist cover film removal block 14.

The interface block 16 includes an eighth central robot CR8, a sending buffer unit SBF, an interface transporting mechanism IFR, and edge exposure units EEW. Further, each of substrate platforms PASS15 and PASS16 and a return buffer unit RBF, described later, are provided below the edge exposure units EEW. The eighth central robot CR8 has hands CRH13 and CRH14 provided one above the other for receiving and transferring the substrates W, and the interface transporting mechanism IFR has hands H1 and H2 provided one above the other for receiving and transferring the substrates W.

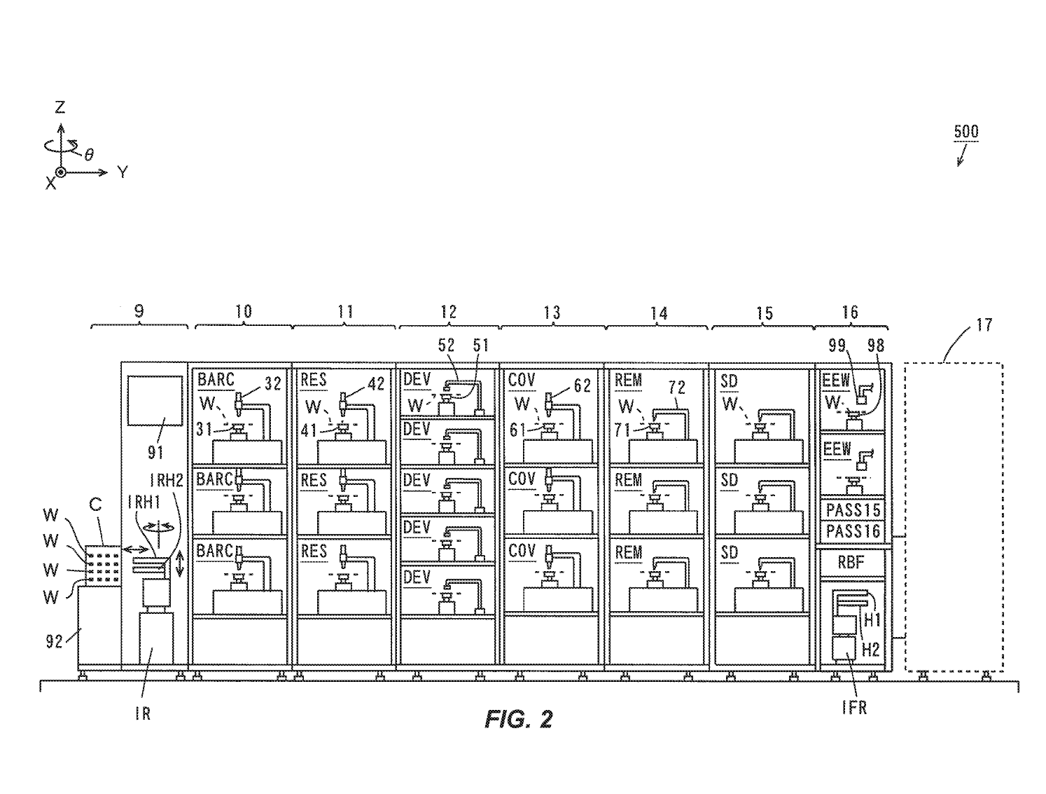

FIG. 2 is a side view of the substrate processing apparatus 500 shown in FIG. 1 as viewed from the +X direction.

The coating processing group 30 (see FIG. 1) in the anti-reflection film processing block 10 has a vertical stack of three coating units BARC. Each of the coating units BARC comprises a spin chuck 31 for rotating the substrate W with the substrate W held in a horizontal attitude by suction, and a supply nozzle 32 for supplying a coating liquid for an anti-reflection film to the substrate W held on the spin chuck 31.

Each of the coating units BARC comprises a removal nozzle (not shown) for removing the anti-reflection film formed at a peripheral edge of the substrate W. The details of this process are described throughout the present specification and more particularly below.

The coating processing group 40 (see FIG. 1) in the resist film processing block 11 has a vertical stack of three coating units RES. Each of the coating units RES comprises a spin chuck 41 for rotating the substrate W with the substrate W held in a horizontal attitude by suction, and a supply nozzle 42 for supplying a coating liquid for a resist film to the substrate W held on the spin chuck 41. Each of the coating units RES comprises a removal nozzle (not shown) for removing the resist film formed at the peripheral edge of the substrate W. The details of this process are described throughout the present specification and more particularly below.

The development processing group 50 (see FIG. 1) in the development processing block 12 has a vertical stack of five development processing units DEV. Each of the development processing units DEV comprises a spin chuck 51 for rotating the substrate W with the substrate W held in a horizontal attitude by suction, and a supply nozzle 52 for supplying a development liquid to the substrate W held on the spin chuck 51.

The coating processing group 60 (see FIG. 1) in the resist cover film processing block 13 has a vertical stack of three coating units COV. Each of the coating units COV comprises a spin chuck 61 for rotating the substrate W with the substrate W held in a horizontal attitude by suction, and a supply nozzle 62 for supplying a coating liquid for a resist cover film to the substrate W held on the spin chuck 61. Materials having a low affinity for resists and water (materials having low reactivity to resists and water) can be used as the coating liquid for the resist cover film. An example of the coating liquid is fluororesin. Each of the coating units COV forms a resist cover film on the resist film formed on the substrate W by applying the coating liquid onto the substrate W while rotating the substrate W. Each of the coating units COV comprises a removal nozzle (not shown) for removing the resist cover film formed at the peripheral edge of the substrate W. The details of this process are described throughout the present specification and more particularly below.

The removal processing group 70b (see FIG. 1) in the resist cover film removal block 14 has a vertical stack of three removal units REM. Each of the removal units REM comprises a spin chuck 71 for rotating the substrate W with the substrate W held in a horizontal attitude by suction, and a supply nozzle 72 for supplying a removal liquid (e.g. fluororesin) capable of dissolving the resist cover film to the substrate W held on the spin chuck 71. Each of the removal units REM removes the resist cover film formed on the substrate W by applying the removal liquid onto the substrate W while rotating the substrate W.

Note that a method of removing the resist cover film in the removal unit REM is not limited to the above-mentioned example. For example, the resist cover film may be removed by supplying the removal liquid onto the substrate W while moving a slit nozzle above the substrate W.

The cleaning/drying processing group 80 (see FIG. 1) in the cleaning/drying processing block 15 has a stack of three cleaning/drying processing units SD.

The interface block 16 has a vertical stack of two edge exposure units EEW, substrate platforms PASS15 and PASS16, and return buffers RBF, and has an eighth central robot CR8 (see FIG. 1) and an interface transporting mechanism IFR arranged therein. Each of the edge exposure units EEW comprises a spin chuck 98 for rotating the substrate W with the substrate held in a horizontal attitude by suction, and a light irradiator 99 for exposing a peripheral edge of the substrate W held on the spin chuck 98.

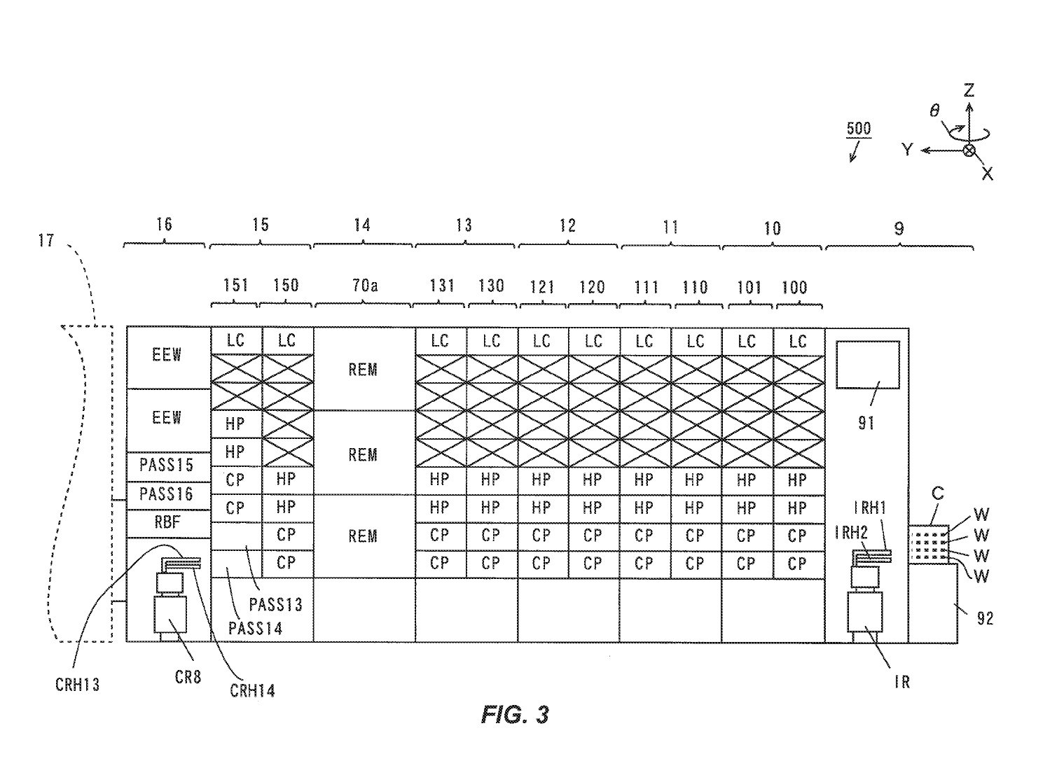

FIG. 3 is a side view of the substrate processing apparatus 500 shown in FIG. 1 as viewed from the −X direction.

In the anti-reflection film processing block 10, the thermal processing group 100 has a vertical stack of two heating units (hot plates) HP and two cooling units (cooling plates) CP, and the thermal processing group 101 has a vertical stack of two heating units HP and two cooling units CP. Each of the thermal processing groups 100 and 101 also has a local controller LC for controlling the respective temperatures of the cooling units CP and the heating units HP arranged in its uppermost part.

In the resist film processing block 11, the thermal processing group 110 has a vertical stack of two heating units HP and two cooling units CP, and the thermal processing group 111 has a vertical stack of two heating units HP and two cooling units CP. Each of the thermal processing groups 110 and 111 also has a local controller LC for controlling the respective temperatures of the cooling units CP and the heating units HP arranged in its uppermost part.

In the development processing block 12, the thermal processing group 120 has a vertical stack of two heating units HP and two cooling units CP, and the thermal processing group 121 has a vertical stack of two heating units HP and two cooling units CP. Each of the thermal processing groups 120 and 121 also has a local controller LC for controlling the respective temperatures of the cooling unit CP and the heating unit HP arranged in its uppermost part.

In the resist cover film processing block 13, the thermal processing group 130 has a vertical stack of two heating units HP and two cooling units CP, and the thermal processing group 131 has a vertical stack of two heating units HP and two cooling units CP. Each of the thermal processing groups 130 and 131 also has a local controller LC for controlling the respective temperatures of the cooling unit CP and the heating unit HP arranged in its uppermost part.

The removal processing group 70a in the resist cover film removal block 14 has a vertical stack of three removal units REM.

In the cleaning/drying processing block 15, the thermal processing group 150 has a vertical stack of two heating units HP and two cooling units CP, and the thermal processing group 151 has a vertical stack of two heating units HP, two cooling units CP, and substrate platforms PASS13 and PASS14. Each of the thermal processing groups 150 and 151 has a local controller LC for controlling the respective temperatures of the cooling units CP and the heating units HP arranged in its uppermost part.

The respective numbers of coating units BARC, RES, and COV, cleaning/drying processing units SD, removal units REM, development processing units DEV, heating units HP, and cooling units CP may be changed, as needed, depending on the processing speed of each of the blocks.

### (2) Operation of Substrate Processing Apparatus

The operation of the substrate processing apparatus 500 according to the present embodiment is described with reference to FIGS. 1 to 3. Carriers C that store a plurality of substrates W in multiple stages are respectively carried onto the carrier platforms 92 in the indexer block 9. The indexer robot IR takes out the unprocessed substrate W that is stored in the carrier C using the upper hand IRH1. Thereafter, the indexer robot IR rotates in the ±θ direction while moving in the ±X direction, to place the unprocessed substrate W on the substrate platform PASS1.

Although FOUPs (Front Opening Unified Pods) are adopted as the carriers C in the present embodiment, the present invention is not limited to the same. For example, SMIF (Standard Mechanical Inter Face) pods, or OCs (Open Cassettes) that expose the stored substrates W to outside air may be used.

Furthermore, although linear-type transport robots that move their hands forward or backward by linearly sliding them to the substrate W are respectively used as the indexer robot IR, the second to eighth central robots CR2 to CR8, and the interface transporting mechanism IFR, the present invention is not limited to the same. For example, multi-joint type transport robots that linearly move their hands forward and backward by moving their joints may be used.

The substrate W placed on the substrate platform PASS1 is received by the second central robot CR2 in the anti-reflection film processing block 10. The second central robot CR2 carries the substrate W into the coating processing group 30. In the coating processing group 30, each of the coating units BARC forms a coating of an anti-reflection film on the substrate W in order to reduce a standing wave or halation generated during the exposure processing. Furthermore, in the coating processing group 30, the coating unit BARC removes the anti-reflection film formed at the peripheral edge of the substrate W in a predetermined range.

Thereafter, the second central robot CR2 takes out the substrate W that has been subjected to the coating processing from the coating processing group 30, and carries the substrate W into the thermal processing group 100 or 101. Then, the second central robot CR2 takes out the thermally processed substrate W from the thermal processing group 100 or 101, and places the substrate W on the substrate platform PASS3. The substrate W placed on the substrate platform PASS3 is received by the third central robot CR3 in the resist film processing block 11. The third central robot CR3 carries the substrate W into the coating processing group 40. In the coating processing group 40, each of the coating units RES forms a coating of a resist film on the substrate W on which the coating of the anti-reflection film has been formed. Furthermore, in the coating processing group 40, the coating unit RES removes the resist film formed at the peripheral edge of the substrate W in a predetermined range.

Thereafter, the third central robot CR3 takes out the substrate W that has been subjected to the coating processing from the coating processing group 40, and carries the substrate W into the thermal processing group 110 or 111. Then, the third central robot CR3 takes out the thermally processed substrate W from the thermal processing group 110 or 111, and places the substrate W on the substrate platform PASS5. The substrate W placed on the substrate platform PASS5 is received by the fourth central robot CR4 in the development processing block 12. The fourth central robot CR4 places the substrate W on the substrate platform PASS7.

The substrate W placed on the substrate platform PASS7 is received by the fifth central robot CR5 in the resist cover film processing block 13. The fifth central robot CR5 carries the substrate W into the coating processing group 60. In the coating processing group 60, each of the coating units COV forms a coating of a resist cover film on the resist film, as described above. Furthermore, in the coating processing group 60, the coating unit COV removes the resist cover film formed at the peripheral edge of the substrate W in a predetermined range.

Therefore, the fifth central robot CR5 takes out the substrate W that has been subjected to the coating processing from the coating processing group 60, and carries the substrate W into the thermal processing group 130 or 131. Then, the fifth central robot CR5 takes out the thermally processed substrate W from the thermal processing group 130 or 131, and places the substrate W on the substrate platform PASS9. The substrate W placed on the substrate platform PASS9 is received by the sixth central robot CR6 in the resist cover film removal block 14. The sixth central robot CR6 places the substrate W on the substrate platform PASS11.

The substrate W placed on the substrate platform PASS11 is received by the seventh central robot CR7 in the cleaning/drying processing block 15. The seventh central robot CR7 places the substrate W received from the substrate platform PASS11 on the substrate platform PASS13. The substrate W placed on the substrate platform PASS13 is received by the eighth central robot CR8 in the interface block 16. The eighth central robot CR8 places the substrate W on the substrate platform PASS15. The eighth central robot CR8 may carry the substrate W into an edge exposure unit EEW. In this case, in the edge exposure unit EEW, the peripheral edge of the substrate W is subjected to the exposure processing.

The interface transporting mechanism IFR carries the substrate W placed on the substrate platform PASS15 into a substrate carry-in section 17a (see FIG. 1.) in the exposure device 17. When the exposure device 17 cannot receive the substrate W, the substrate W is temporarily stored in the sending buffer unit SBF.

After the exposure device 17 subjects the substrate W to the exposure processing, the interface transporting mechanism IFR takes out the substrate W from an exposure device 17b (see FIG. 1) in the exposure device 17 and carries the same into the cleaning/drying processing group 80 in the cleaning/drying processing block 15. In the cleaning/drying processing unit SD in the cleaning/drying processing group 80, the substrate W after the exposure processing is subjected to cleaning and drying processing.

After the cleaning/drying processing group 80 subjects the substrate W after the exposure processing to the cleaning and drying processing, the interface transporting mechanism IFR takes out the substrate W from the cleaning/drying processing group 80, and places the same on the substrate platform PASS16. The details of the operation of the interface transporting mechanism IFR in the interface block 16 are described throughout the present specification and more particularly below. When the cleaning/drying processing group 80 cannot temporarily perform the cleaning and drying processing due to a failure or the like, the substrate W after the exposure processing can be temporarily stored in the return buffer unit RBF in the interface block 16.

The substrate W placed on the substrate platform PASS16 is received by the eighth central robot CR8 in the interface block 16. The eighth central robot CR8 carries the substrate W into the thermal processing group 151 in the cleaning/drying processing block 15. In the thermal processing group 151, the substrate W is subjected to post-exposure bake (PEB). Thereafter, the eighth central robot CR8 takes out the substrate W from the thermal processing group 151, and places the substrate W on the substrate platform PASS14.

Although the thermal processing group 151 subjects the substrate W to post-exposure bake in the present embodiment, the thermal processing group 150 may subject the substrate W to post-exposure bake.

The substrate W placed on the substrate platform PASS14 is received by the seventh central robot CR7 in the cleaning/drying processing block 15. The seventh central robot CR7 places the substrate W on the substrate platform PASS12. The substrate W placed on the substrate platform PASS12 is received by the sixth central robot CR6 in the resist cover film removal block 14. The sixth central robot CR6 carries the substrate W into the resist cover film removal processing group 70a or 70b. In the resist cover film removal processing group 70a or 70b, a removal unit REM removes the resist cover film on the substrate W.

Thereafter, the sixth central robot CR6 takes out the processed substrate W from the resist cover film removal processing group 70a or 70b, and places the substrate W on the substrate platform PASS10. The substrate W placed on the substrate platform PASS10 is received by the fifth central robot CR5 in the resist cover film processing block 13. The fifth central robot CR5 places the substrate W on the substrate platform PASS8. The substrate W placed on the substrate platform PASS8 is received by the fourth central robot CR4 in the development processing block 12. The fourth central robot CR4 carries the substrate W into the development processing group 50. In the development processing group 50, a development processing unit DEV subjects the substrate W to development processing.

Thereafter, the fourth central robot CR4 takes out the substrate W after the development processing from the development processing group 50, and carries the substrate W into the thermal processing group 120 or 121. The fourth central robot CR4 then takes out the substrate W after the thermal processing from the thermal processing group 120 or 121, and places the substrate W on the substrate platform PASS6. The substrate W placed on the substrate platform PASS6 is received by the third central robot CR3 in the resist film processing block 11. The third central robot CR3 places the substrate W on the substrate platform PASS4.

The substrate W placed on the substrate platform PASS4 is received by the second central robot CR2 in the anti-reflection film processing block 10. The second central robot CR2 places the substrate W on the substrate platform PASS2. The substrate W placed on the substrate platform PASS2 is stored in the carrier C by the indexer robot IR in the indexer block 9.

In the following description, the removal processing of the anti-reflection film, the resist film, and the resist cover film formed at the peripheral edge of the substrate W, respectively, by the coating units BARC, RES, and COV will be generically referred to as peripheral edge film removal processing.

### (3) Coating Unit

The coating unit BARC in the coating processing group 30 for anti-reflection film, the coating unit RES in the coating processing group 40 for resist film, and the coating unit COV in the coating processing group 60 for resist cover film have the same configuration. The configuration of the coating unit BARC out of the three types of coating units BARC, RES, and COV will be described in detail using the drawings. Note that the main controller (controller) 91 shown in FIG. 1 controls the operation of each of constituent elements in each of the coating units BARC, RES, and COV.

(3-a) Configuration of Coating Unit

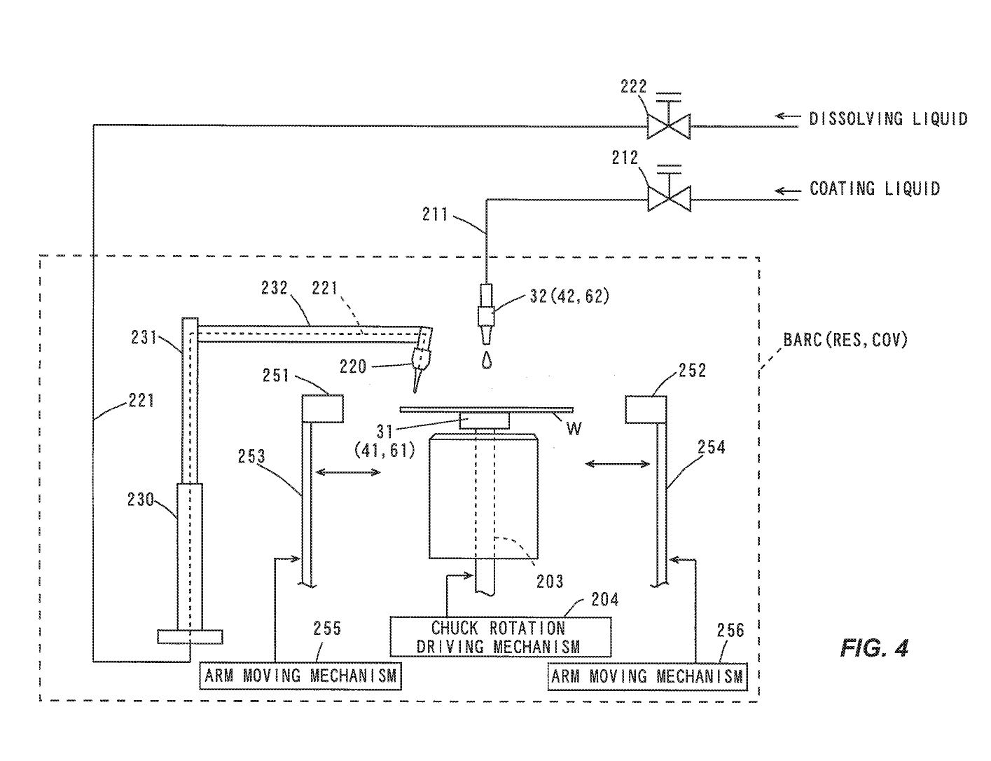

FIG. 4 is a diagram for explaining the configuration of the coating unit BARC. As shown in FIG. 4, the coating unit BARC comprises a spin chuck 31 for rotating a substrate W about a vertical rotation shaft passing through the center of the substrate W while horizontally holding the substrate W.

The spin chuck 31 is secured to an upper end of a rotation shaft 203, which is rotated by a chuck rotation driving mechanism 204. A suction path (not shown) is formed in the spin chuck 31. Air inside the suction path is exhausted with the substrate W placed on the spin chuck 31, to adsorb a lower surface of the substrate W on the spin chuck 31 under vacuum, so that the substrate W can be held in a horizontal attitude. A supply nozzle 32 is provided above the spin chuck 31. The supply nozzle 32 is provided so as to be movable above the spin chuck 31. A coating liquid supply pipe 211 is connected to the supply nozzle 32. A valve 212 is inserted through the coating liquid supply pipe 211. A coating liquid for an anti-reflection film is supplied to the coating liquid supply pipe 211. The amount of the coating liquid supplied onto the substrate W through the coating liquid supply pipe 211 and the supply nozzle 32 can be adjusted by controlling the opening of the valve 212.

A motor 230 is provided outside the spin chuck 31. A rotation shaft 231 is connected to the motor 230. An arm 232 is connected to the rotation shaft 231 so as to horizontally extend, and a removal nozzle 220 is provided at a front end of the arm 232.

At the time of the peripheral edge film removal processing, the motor 230 causes the rotation shaft 231 to rotate while causing the arm 232 to swing. This causes the removal nozzle 220 to move to above the peripheral edge of the substrate W held by the spin chuck 31. In this state, the tip of the removal nozzle 220 is opposed to the peripheral edge of the substrate W.

A removal liquid supply pipe 221 is provided so as to pass through the motor 230, the rotation shaft 231, and the arm 232. The removal liquid supply pipe 221 is connected to the removal nozzle 220. A valve 222 is inserted through the removal liquid supply pipe 221, and a removal liquid for dissolving the anti-reflection film is supplied to the removal liquid supply pipe 221. An example of the removal liquid used in the coating unit BARC is an organic solvent for dissolving the anti-reflection film.

The amount of the removal liquid supplied onto the substrate W through the removal liquid supply pipe 221 and the removal nozzle 220 can be adjusted by controlling the opening of the valve 222 during the peripheral edge film removal processing.

In this coating unit BARC, the substrate W is carried there into by the second central robot CR2, and is placed on the spin chuck 31. In this state, the substrate W is rotated by the spin chuck 31. The coating liquid is supplied onto the rotated substrate W from the supply nozzle 32, to spread over a surface of the substrate W. Thereafter, the supply of the coating liquid to the substrate W is stopped while the rotation of the substrate W is continued so that the coating liquid on the surface of the substrate W is dried. This causes the anti-reflection film to be formed on the substrate W.

The motor 230 then drives the rotation shaft 231, so that the removal nozzle 220 provided in the arm 232 moves to above the peripheral edge of the rotated substrate W. The removal liquid is supplied toward the peripheral edge of the substrate W from the removal nozzle 220. At this time, the substrate W is rotated so that the anti-reflection film formed at the peripheral edge of the substrate W is removed (i.e., peripheral edge film removal processing).

In the foregoing, the second central robot CR2 shown in FIG. 1 that carries the substrate W into the coating unit BARC places the substrate W such that the center of the substrate W coincides with the axis of the spin chuck 31. When the operation precision of the second central robot CR2 is low, however, the substrate W may, in some cases, be placed in a state where the center of the substrate W does not coincide with the axis of the spin chuck 31.

When the substrate W is held by the spin chuck 31 in this state, the substrate W is rotated in an eccentric state during the peripheral edge film removal processing. In this case, the removal liquid cannot be uniformly supplied over the whole periphery of the peripheral edge of the substrate W. Consequently, the anti-reflection film at the peripheral edge of the substrate W cannot be uniformly removed over the whole periphery of the substrate W. In the present embodiment, therefore, the position of the substrate W is corrected before the peripheral edge film removal processing for the substrate W.

A pair of guide arms 251 and 252 is provided outside the spin chuck 31. The guide arms 251 and 252 are arranged opposite to each other with the substrate W held by the spin chuck 31 interposed therebetween. The guide arms 251 and 252 are respectively supported by supporting members 253 and 254 extending downward. The supporting members 253 and 254 respectively move in the horizontal direction by arm moving mechanisms 255 and 256. As the supporting members 253 and 254 move, the guide arms 251 and 252 respectively move in a direction nearer to or away from the substrate W. The positions where the guide arms 251 and 252 are farthest away from the outer periphery of the substrate W are respectively referred to as waiting positions.

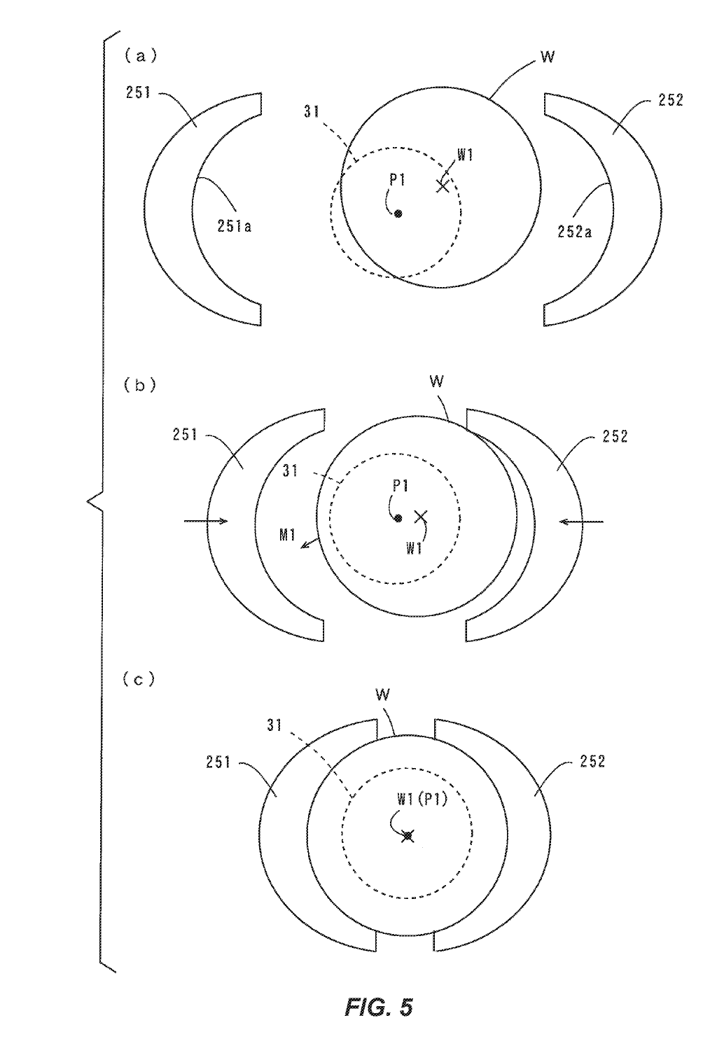

The details of the shape and operation of the guide arms 251 and 252 will be herein described with reference to FIG. 5. FIG. 5 is a top view showing the operations of the guide arms 251 and 252 and the substrate W. As shown in FIGS. 5(a) and 5(c), the guide arm 251 has a semi-cylindrical shape, and has its inner surface 251a formed along a circular arc of the substrate W. The guide arm 252 has a shape equal to the guide arm 251, and has its inner surface 252a formed along the circular arc of the substrate W. The guide arms 251 and 252 are arranged so as to be symmetrical with the axis P1 of the spin chuck 31 used as its center. Note that the axis P1 of the spin chuck 31 is equal to the axis of the rotation shaft 203 (FIG. 4).

The operation of the guide arms 251 and 252 is described as follows. First, the second central robot CR2 (FIG. 1) carries the substrate W into the coating unit BARC, and places the substrate W on the spin chuck 31 with the guide arms 251 and 252 at the respective waiting positions farthest away from the axis P1 of the spin chuck 31, as shown in FIG. 5(a).

The guide arms 251 and 252 then respectively move toward the axis P1 of the spin chuck 31 at equal speeds, as shown in FIG. 5(b). At this time, in a case where the center W1 of the substrate W is shifted from the axis P1 of the spin chuck 31, at least one of the guide arms 251 and 252 presses the substrate W. Thus, the substrate W moves such that the center W1 of the substrate W comes closer to the axis P1 of the spin chuck 31 (see an arrow M1 in FIG. 5(b)).

When the guide arms 251 and 252 move toward the axis P1 of the spin chuck 31, as shown in FIG. 5(c), the substrate W is sandwiched between the guide arms 151 and 252, so that the center W1 of the substrate W coincides with the axis P1 of the spin chuck 31. The guide arms 251 and 252 thus correct the position of the substrate W such that the center W1 of the substrate W coincides with the axis P1 of the spin chuck 31.

Note that the operation of the guide arms 251 and 252 is performed after the substrate W is placed on the spin chuck 31 by the second central robot CR2 and before it is sucked in the spin chuck 31 under vacuum.

As described above, the two types of coating units RES and COV also have the same configuration as the coating unit BARC.

However, the third central robot CR3 shown in FIG. 1 performs an operation for carrying the substrate W into and out of the coating unit RES. In the coating unit RES, a resist liquid is used as the coating liquid. A removal liquid used in the coating unit RES dissolves a resist film. An example of this removal liquid is an ether-based organic solvent for dissolving the resist film.

The fifth central robot CR5 shown in FIG. 1 performs an operation for carrying the substrate W into and out of the coating unit COV. In the coating unit COV, a coating liquid for a resist cover film is used as the coating liquid. A removal liquid used in the coating unit COV dissolves the resist cover film. An example of this removal liquid is an alcohol-based organic solvent for dissolving the resist cover film.

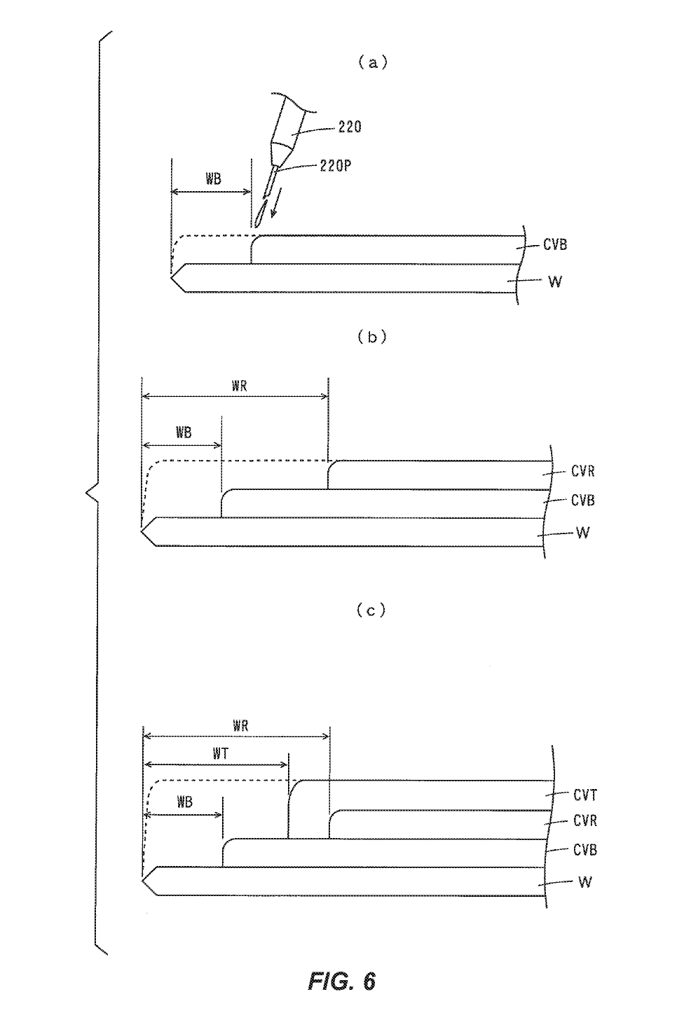

FIG. 6 is a diagram showing the procedure for forming the anti-reflection film, the resist film, and the resist cover film on the surface of the substrate W and a removal region of each of the films. First, in the coating unit BARC, an anti-reflection film CVB is formed on the surface of the substrate W, as shown in FIG. 6(a). The removal liquid is discharged into a peripheral edge of the anti-reflection film CVB from a needle-shaped nozzle portion 220P in the removal nozzle 220, so that an annular region at the peripheral edge of the anti-reflection film CVB formed on the substrate W is removed. A removal region in the annular region of the anti-reflection film CVB is indicated by WB.

Then, in the coating unit RES, a resist film CVR is formed on the respective surfaces of the substrate W and the anti-reflection film CVB, as shown in FIG. 6(b). The removal liquid is discharged into a peripheral edge of the resist film CVR from the needle-shaped nozzle portion 220P in the removal nozzle 220, so that an annular region at the peripheral edge of the resist film CVR formed on the substrate W is removed. A removal region in the annular region of the resist film CVR is indicated by WR.

Thereafter, in the coating unit COV, a resist cover film CVT is formed on the respective surfaces of the substrate W, the anti-reflection film CVB, and the resist film CVR, as shown in FIG. 6(c). The removal liquid is discharged into a peripheral edge of the resist cover film CVT from the needle-shaped nozzle portion 220P in the removal nozzle 220, so that an annular region at the peripheral edge of the resist cover film CVT formed on the substrate W is removed. A removal region in the annular region of the resist cover film CVT is indicated by WT.

In this case, the removal region WB of the anti-reflection film CVB, the removal region WT of the resist cover film CVT, and the removal region WR of the resist film CVR are set so as to increase in this order. This causes the following effects to be obtained.

Generally, the anti-reflection film CVB formed on the substrate W is more difficult to strip from the substrate W, as compared with the resist film CVR and the resist cover film CVT. Since the resist film CVR and the resist cover film CVT are not formed on the surface of the substrate W by making the removal region WB of the anti-reflection film CVB smaller than the respective removal regions WR and WT of the resist film CVR and the resist cover film CVT, therefore, the stripping of the film from the surface of the substrate W is reduced.

The surface of the resist film CVR can be completely covered with the resist cover film CVT by making the removal region WR of the resist film CVR larger than the removal region WT of the resist cover film CVT. This can prevent the resist film CVR from being leeched into the liquid during the exposure processing.

In the present embodiment, the position of the substrate W is corrected before the peripheral edge film removal processing for the substrate W such that the center W1 of the substrate W coincides with the axis P1 of each of the spin chucks 31, 41, and 61. The peripheral edge film removal processing for the substrate W is performed using the needle-shaped nozzle portion 220P having a small diameter. This allows the film at the peripheral edge of the substrate W to be accurately removed with high precision during the peripheral edge film removal processing.

(3-b) Another Example Configuration of the Coating Unit

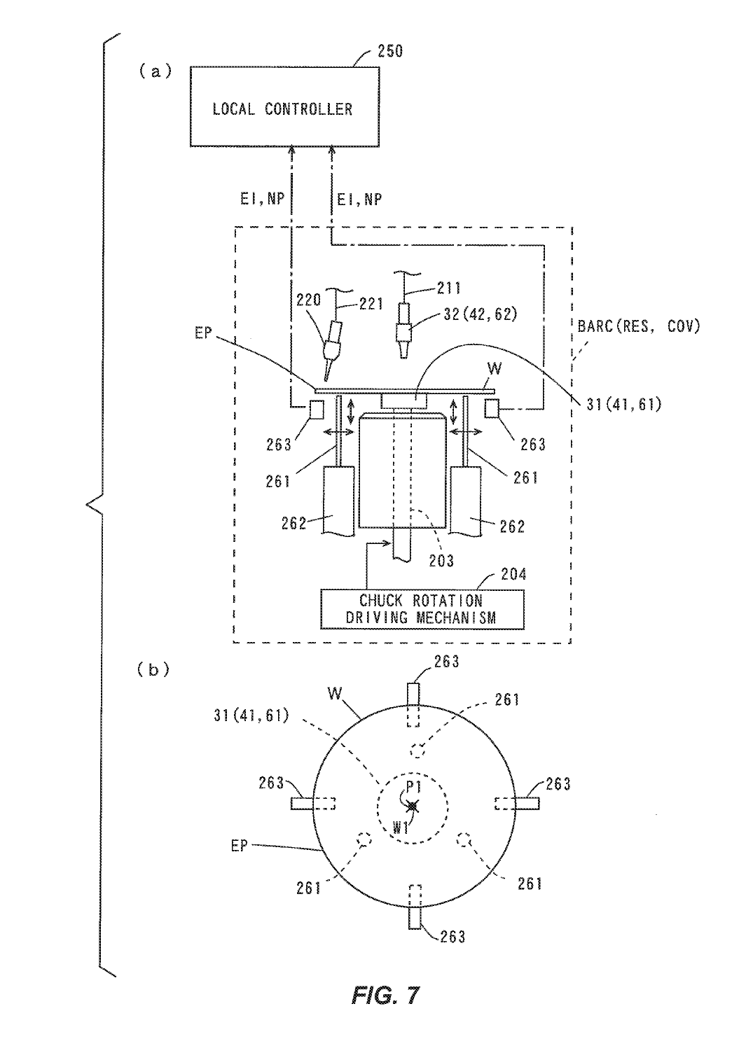

All the coating units BARC, RES, and COV may have the following configuration. FIG. 7 is a diagram for explaining another example of the configuration of the coating unit BARC. FIG. 7(a) is a side view showing another example of the configuration of the coating unit BARC, and FIG. 7(b) is a top view of a part of the coating unit BARC shown in FIG. 7(a). The difference between the coating unit BARC shown in FIG. 7 and the coating unit BARC shown in FIG. 4 will be described.

As shown in FIGS. 7(a) and 7(b), three or more correction pins 261 extending in the vertical direction are provided beside a rotation shaft 203 and a spin chuck 31. In the present embodiment, three correction pins 261 are provided. The correction pins 261 are spaced at substantially equal angles with the axis P1 of the spin chuck 31 used as its center. The three correction pins 261 are movable integrally with one another in the vertical direction and the horizontal direction by pin driving devices 262.

Four eccentric sensors 263 are provided in the vicinity of a peripheral edge EP of a substrate W outside the correction pins 261 and on the spin chuck 31. The four eccentric sensors 263 are spaced at equal angles with the axis P1 of the spin chuck 31 used as its center. The eccentric sensor 263 detects the amount of eccentricity of the substrate W from the axis P1 of the spin chuck 31 and the position of a notch of the substrate W, and feeds an eccentric signal EI and a notch position signal NP to a local controller 250 for controlling the operation of the coating unit BARC. Here, the notch of the substrate W means a notch formed at the peripheral edge EP of the substrate W in order to easily determine the direction or the like of the substrate W. An example of the eccentric sensor 263 is a CCD (Charge Coupled Device) line sensor.

In this example, a motor 230 to which a rotation shaft 231 is connected is also provided outside the spin chuck 31, as in the example shown in FIG. 4, which is not illustrated. An arm 232 is connected to the rotation shaft 231 so as to horizontally extend, and a removal nozzle 220 is provided at a front end of the arm 232. In the coating unit BARC shown in FIG. 7, the eccentric sensors 263 detect the amount of eccentricity of the substrate W, and the correction pins 261 correct the position of the substrate W.

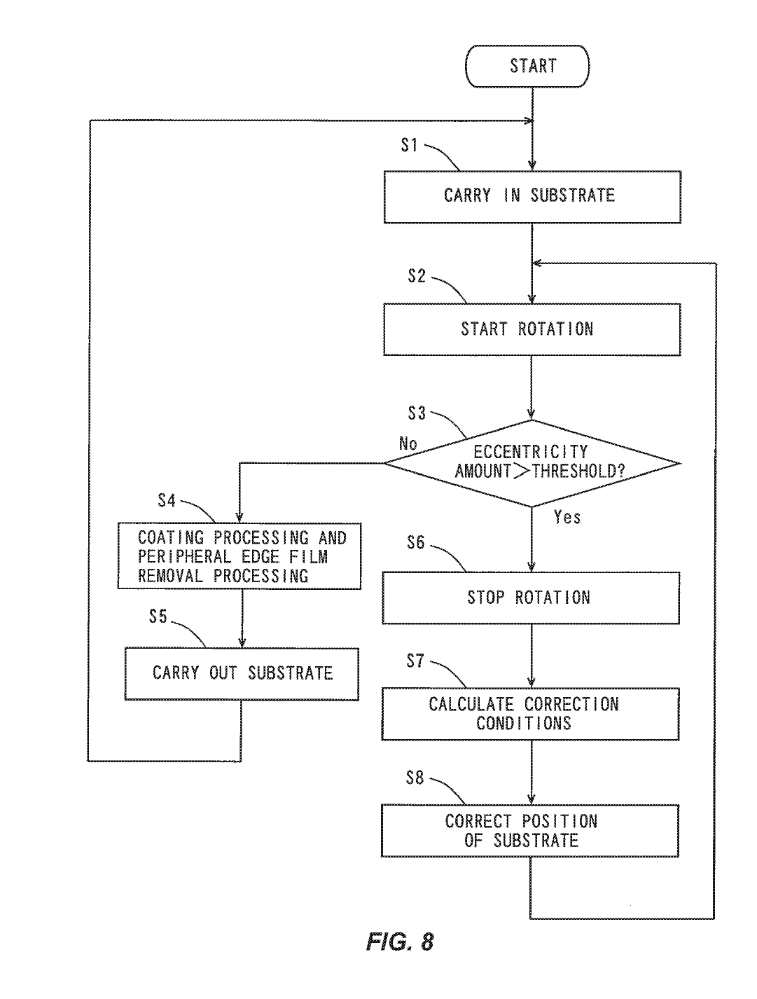

Here, the correction of the position of the substrate W in the coating unit BARC shown in FIG. 7 will be described with reference to FIG. 8. FIG. 8 is a flow chart showing an example of control of the coating unit BARC by the local controller 250. As shown in FIG. 8, the local controller 250 causes the second central robot CR2 to carry the substrate W into the coating unit BARC (step S1). The substrate W carried into the coating unit BARC is held by the spin chuck 31. The local controller 250 then causes a chuck rotation driving mechanism 204 to start the rotation of the rotation shaft 203, to start the rotation of the substrate W held in the spin chuck 31 (step S2).

The local controller 250 then determines whether or not the amount of eccentricity of the substrate W from the axis of the rotation shaft 203 is more than a threshold value on the basis of the eccentric signal EI fed from the eccentric sensor 263 (step S3). When the amount of eccentricity of the substrate W from the axis of the rotation shaft 203 is not more than the threshold value in the step S3, the local controller 250 performs anti-reflection film coating processing by a supply nozzle 32 and peripheral edge film removal processing by the removal nozzle 220 (step S4). Thereafter, the local controller 250 causes the second central robot CR2 to carry the substrate W out of the coating unit BARC (step S5). The procedure is returned to the step S1.

When the amount of eccentricity of the substrate W from the axis of the rotation shaft 203 is more than the threshold value in the step S3, the local controller 250 causes the chuck rotation driving mechanism 204 to stop the rotation of the rotation shaft 203, to stop the rotation of the substrate W (step S6), and releases the holding of the substrate W by the spin chuck 31.

The local controller 250 then calculates the position correction conditions of the substrate W on the basis of the eccentric signal E1 and the notch position signal NP (step S7). Here, the position correction conditions of the substrate W are the movement conditions of the substrate W for matching the center W1 (FIG. 5) of the substrate W with the axis P1 (FIG. 5) of the spin chuck 31, and include the movement direction and the movement distance of the substrate W.

The local controller 250 then causes the correction pins 261 to correct the position of the substrate W on the basis of the results of the calculation of the position correction conditions of the substrate W in the step S6 (step S8). Specifically, the three correction pins 261 integrally move upward to support the substrate W at three points. Then, the correction pins 261 horizontally move such that the center W1 of the substrate W coincides with the axis P1 of the spin chuck 31. The correction pins 261 move downward so that the substrate W is placed on the spin chuck 31. The spin chuck 31 holds the substrate W. This causes the position of the substrate W to be corrected. Thereafter, the procedure is returned to the step S2.

In the step S8, the second central robot CR2 may correct the position of the substrate W in place of the correction pins 261. In the case, the correction pins 261 and the pin driving devices 262 need not be provided, which allows the coating unit BARC to be miniaturized and made lightweight.

Although in the example shown in FIG. 7, the four eccentric sensors 263 are provided within the coating unit BARC, the number of eccentric sensors 263 may be changed, as needed, depending on the size of the substrate W, for example. Although in the example shown in FIG. 7, the amount of eccentricity of the substrate W is detected with the substrate W rotated, the amount of eccentricity of the substrate W may be detected with the rotation of the substrate W stopped. When the amount of eccentricity of the substrate W is detected with the rotation of the substrate W stopped in a case where the number of eccentric sensors 263 provided within the coating unit BARC is one or two, for example, however, an accurate amount of eccentricity cannot, in some cases, be detected depending on the direction of eccentricity of the substrate W. Therefore, it is preferable that the amount of eccentricity of the substrate W is detected with the substrate W rotated in a case where the number of eccentric sensors 263 provided within the coating unit BARC is one or two, for example.

As described in the foregoing, in the coating unit BARC in this example, the eccentric sensor 263 detects the amount of eccentricity of the substrate W. When the amount of eccentricity is more than the threshold value, the correction pins 261 correct the position of the substrate W. This allows the film at the peripheral edge of the substrate W to be accurately removed with high precision during the peripheral edge film removal processing. Since the coating units RES and COV also have the same configuration as the coating unit BARC, the same effects can be obtained.

(3-c) Still Another Example Configuration of the Coating Unit

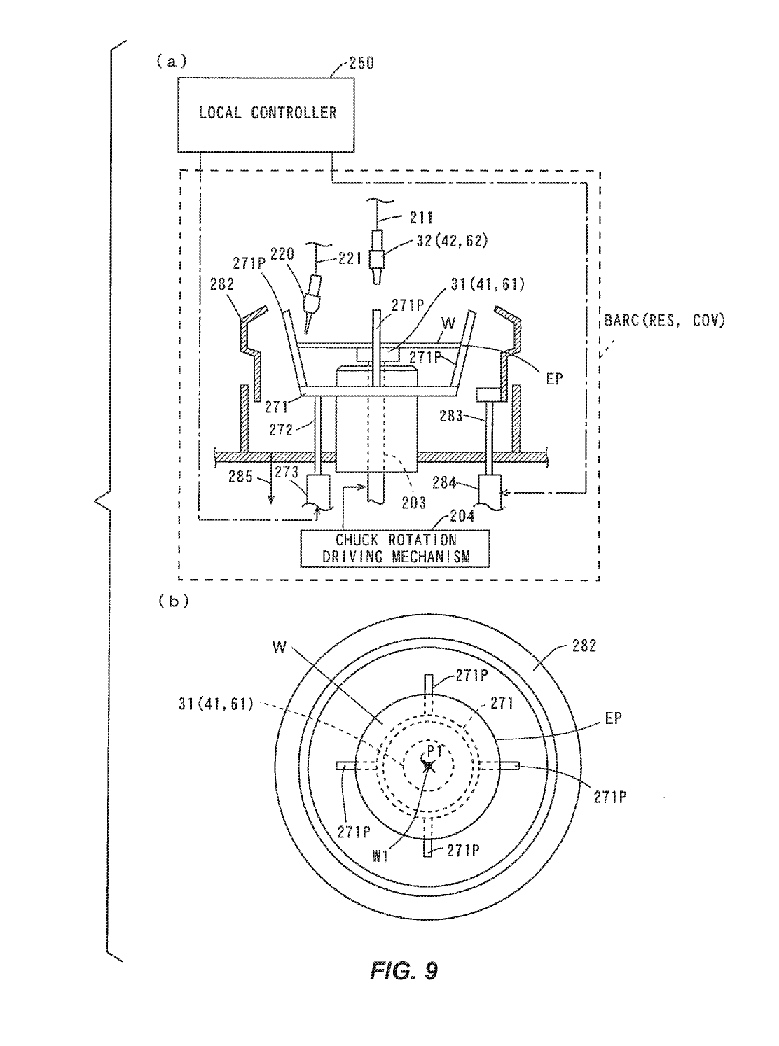

The coating units BARC, RES, and COV may further have the following configuration. FIG. 9 is a diagram for explaining still another example of the configuration of the coating unit BARC. FIG. 9(a) is a side view showing still another example of the configuration of the coating unit BARC, and FIG. 9(b) is a top view of a part of the coating unit BARC shown in FIG. 9(a). The difference between the coating unit BARC shown in FIG. 9 and the coating unit BARC shown in FIG. 4 will be described. As shown in FIGS. 9(a) and 9(b), three or more support pins 271P are spaced at substantially equal angles so as to surround a rotation shaft 203 and a spin chuck 31. In this example, four support pins 271P are provided.

The four support pins 271P are inclined obliquely upward outward with the rotation shaft 203 used as its center by holding their respective lower ends in an annular pin holder 271. The diameter of a circular region surrounded by the lower ends of the four support pins 271P is not more than the diameter of a substrate W, and the diameter of a circular region surrounded by respective upper ends of the four support pins 271P is larger than the diameter of the substrate W. The pin holder 271 is attached to a lifting shaft 272. A local controller 250 controls a pin driving device 273, to raise and lower the lifting shaft 272. This causes the four support pins 271P, together with the pin holder 271, to rise and fall.

A substantially cylindrical processing cup 282 for preventing a cleaning liquid from the substrate W from being scattered outward is provided so as to surround the four support pins 271P and the pin holder 271. The processing cup 282 is attached to a lifting shaft 283 in a cup driving device 284. The local controller 250 controls the cup driving device 284, to raise and lower the lifting shaft 283. This causes the processing cup 282 to rise and fall between a discharged liquid recovery position surrounding a peripheral edge EP of the substrate W held by the spin chuck 31 and a waiting position below the spin chuck 31.

At the time of processing for coating the substrate W with an anti-reflection film and peripheral edge film removal processing, the processing cup 282 rises to the discharged liquid recovery position, and a coating liquid and a removal liquid are respectively supplied to the substrate W from a supply nozzle 32 and a removal nozzle 220. In this state, the coating liquid and the removal liquid scatted from the substrate W flow downward along an inner surface of the processing cup 282. The cleaning liquid that has flown down is discharged outward through a discharge system 285 formed on a bottom surface of the coating unit BARC.

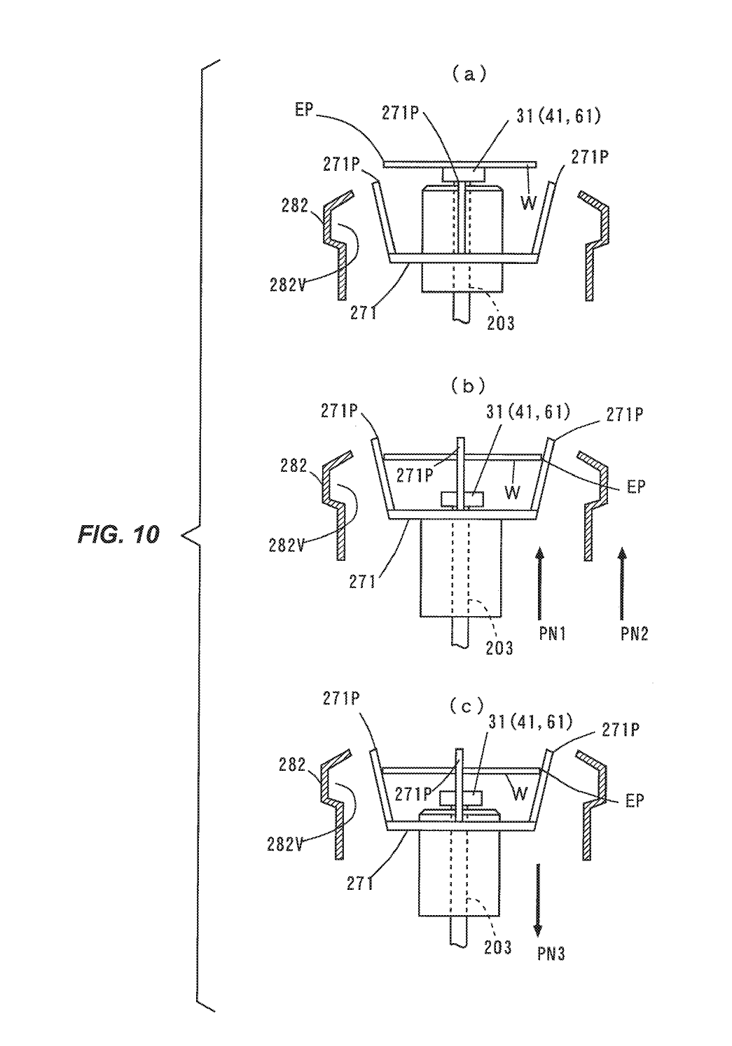

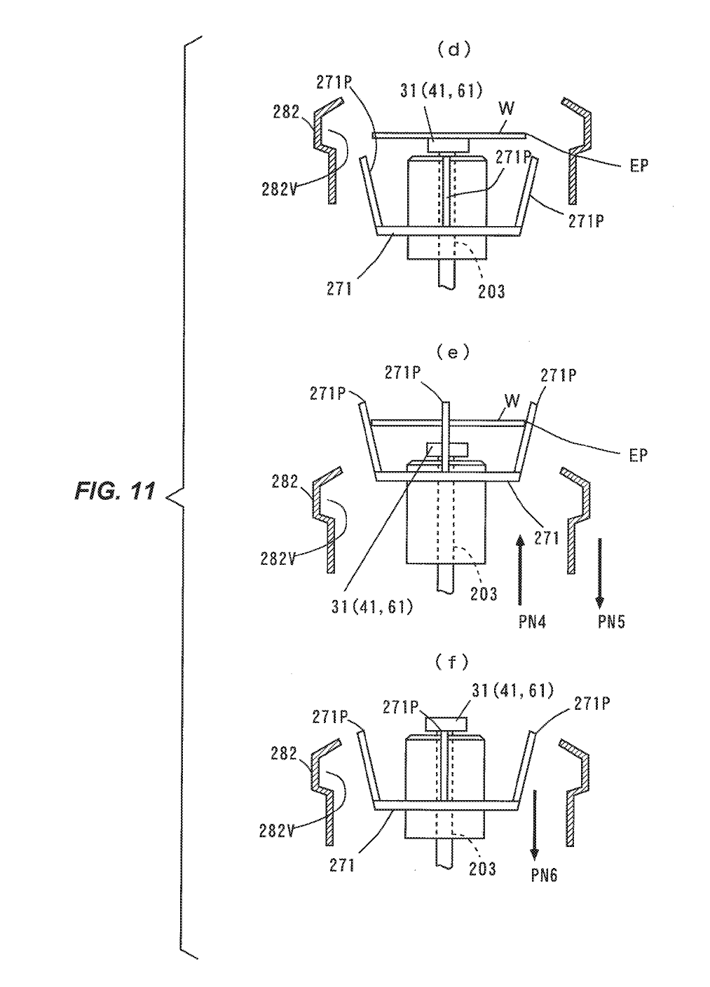

The details of an operation for raising and lowering the four support pins 271P and the processing cup 282 and the function thereof are described as follows. FIGS. 10 and 11 are diagrams for explaining the operation for raising and lowering the four support pins 271P and the processing cup 282 in the coating unit BARC shown in FIG. 9. When the substrate W is carried into the coating unit BARC, as shown in FIG. 10(a), the substrate W is first placed on the spin chuck 31. At this time, both the four support pins 271P and the processing cup 282 are respectively positioned at waiting positions below the spin chuck 31.

When the substrate W is placed on the spin chuck 31, as shown in FIG. 10(b), the pin holder 271 rises (an arrow PN1), and the processing cup 282 also rises (an arrow PN2). Here, the four support pins 271P are inclined obliquely upward outward with the rotation shaft 203 used as its center, as described above. Further, the diameter of the circular region surrounded by the four support pins 271P gradually enlarges in ascending order. When the four support pins 271P rise in a case where the center W1 (FIG. 5) of the substrate W and the axis P1 (FIG. 5) of the spin chuck 31 coincide with each other, the peripheral edge EP of the substrate W abuts against the four support pins 271P almost simultaneously. The substrate W is lifted by the four support pins 271P.

On the other hand, when the four support pins 271P rise in a case where the center W1 of the substrate W and the axis P1 of the spin chuck 31 do not coincide with each other, the peripheral edge EP of the substrate W first abuts against any one to three of the four support pins 271P. At this time, the peripheral edge EP of the substrate W that abuts against the support pin 271P moves in the horizontal direction toward the rotation shaft 203 while sliding along the support pin 271P. The four support pins 271P further rise, to abut against the peripheral edge EP of the substrate W, so that the center W of the substrate W and the axis P1 of the spin chuck 31 coincide with each other. The substrate W is lifted by the four support pins 271P.

Thereafter, the four support pins 271P fall (an arrow PN3), as shown in FIG. 10(c). This causes the four support pins 271P to respectively return to the waiting positions, as shown in FIG. 11(d), so that the substrate W is placed on the spin chuck 31 with the center W1 of the substrate W coinciding with the axis P1 of the spin chuck 31. In this state, the substrate W is held in the spin chuck 31 by suction. The processing for coating the substrate W with the anti-reflection film and the peripheral edge film removal processing are performed within the processing cup 282.

When the processing for coating the substrate W with the anti-reflection film and the peripheral edge film removal processing are terminated, the processing cup 282 falls (an arrow PN5), and the four support pins 271P rise (an arrow PN4), as shown in FIG. 11(e). This causes the substrate W to be lifted. The substrate W lifted by the four support pins 271P is received with the hand CRH1 shown in FIG. 1, and is carried out of the coating unit BARC. Finally, the four support pins 271P respectively fall to the waiting positions (an arrow PN6), as shown in FIG. 11(f).

As described in the foregoing, in the coating unit BARC in this example, the four support pins 271P rise and fall, so that the position of the substrate W is corrected in a simple configuration and easily. This allows the film at the peripheral edge EP of the substrate W to be accurately removed with high precision during the peripheral edge film removal processing. Since the coating units RES and COV also have the same configuration as the coating unit BARC, the same effects can be obtained.

(3-d) Still Another Example Configuration of the Coating Unit

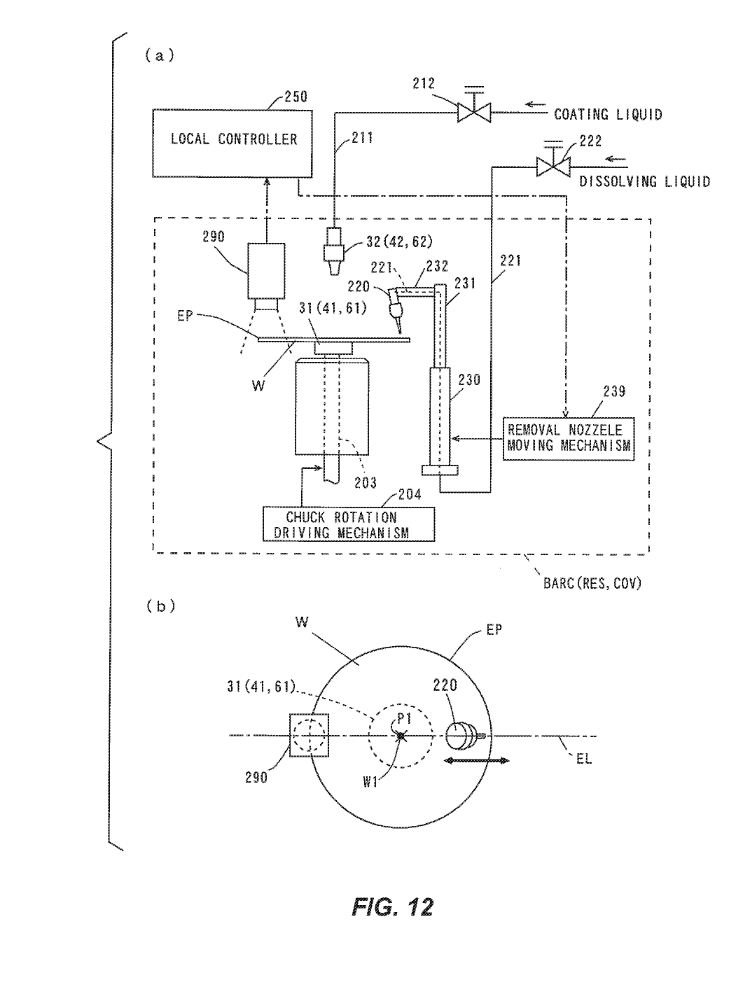

The coating units BARC, RES, and COV may further have the following configuration. FIG. 12 is a diagram for explaining still another example of the configuration of the coating unit BARC. FIG. 12(a) is a side view showing still another example of the configuration of the coating unit BARC, and FIG. 12(b) is a top view of a part of the coating unit BARC shown in FIG. 12(a). The difference between the coating unit BARC shown in FIG. 12 and the coating unit BARC shown in FIG. 4 will be described.

As shown in FIGS. 12(a) and 12(b), a camera 290 is arranged above a spin chuck 31 and in the vicinity of a peripheral edge EP of a substrate W held by the spin chuck 31. The camera 290 is a CCD camera, for example, to pick up the peripheral edge EP of the substrate W held by the spin chuck 31 from above. An image obtained by the camera 290 is given as an electric signal to a local controller 250.

A chuck rotation driving mechanism 204 includes a motor and an encoder. The local controller 250 can detect a rotation angle from a reference position (0 degree) of a rotation shaft 203 rotated and driven by the motor on the basis of an output signal of the encoder.

As shown in FIG. 12(b), the camera 290 and a removal nozzle 220 are opposed to each other with the axis P1 of the spin chuck 31 interposed therebetween during peripheral edge film removal processing for the substrate W. When the center W1 of the substrate W coincides with the axis P1 of the spin chuck 31, the peripheral edge EP of the substrate W is not displaced as the substrate W is rotated on a horizontal line EL passing through the axis P1 of the spin chuck 31.

On the other hand, when the center W1 of the substrate W does not coincide with the axis P1 of the spin chuck 31, the peripheral edge EP of the substrate W is displaced as the substrate W is rotated on a horizontal line connecting the axis P1 of the spin chuck 31 and a shaft along the axis of the camera 290. In this case, the amount of displacement of the peripheral edge EP is changed depending on the rotation angle of the spin chuck 31.

In the following description, the horizontal line connecting the axis P1 of the spin chuck 31 and the shaft along the axis of the camera 290 is referred to as an eccentricity detection line EL. The local controller 250 detects the relationship between the amount of displacement at the peripheral edge EP of the substrate W on the eccentricity detection line EL and the rotation angle of the spin chuck 31 on the basis of the image given from the camera 290.

Furthermore, the local controller 250 causes a removal nozzle moving mechanism 239 to move the removal nozzle 220 on the eccentricity detection line EL on the basis of the relationship between the amount of displacement of the peripheral edge EP and the rotation angle of the spin chuck 31.

Specifically, the local controller 250 rotates the substrate W once, to detect the relationship between a rotation angle from the reference angle of the spin chuck 31 and the amount of displacement of the peripheral edge EP on the eccentricity detection line EL on the basis of the image given from the camera 290 and stores the detected relationship.

The local controller 250 moves the removal nozzle 220 on the eccentricity detection line EL in real time (see an arrow in FIG. 12(b)) such that the relative position (distance) between the rotation center of the substrate W and the tip of the removal nozzle 220 is held on the basis of the stored relationship between the rotation angle and the amount of displacement while the substrate W is being rotated.

Even when the axis P1 of the spin chuck 31 and the center W1 of the substrate W placed on the spin chuck 31 do not coincide with each other during the peripheral edge film removal processing, therefore, the position where the removal nozzle 220 supplies the removal liquid to the substrate W can be kept constant from the peripheral edge EP of the substrate W by keeping the relative position (distance) between the center W1 of the substrate W and the tip of the removal nozzle 220 constant. As a result, it is possible to accurately remove the film at the peripheral edge EP of the substrate W with high precision. Since the coating units RES and COV also have the same configuration as the coating unit BARC, the same effects can be obtained.

(3-e) Still Another Example Configuration of the Coating Unit

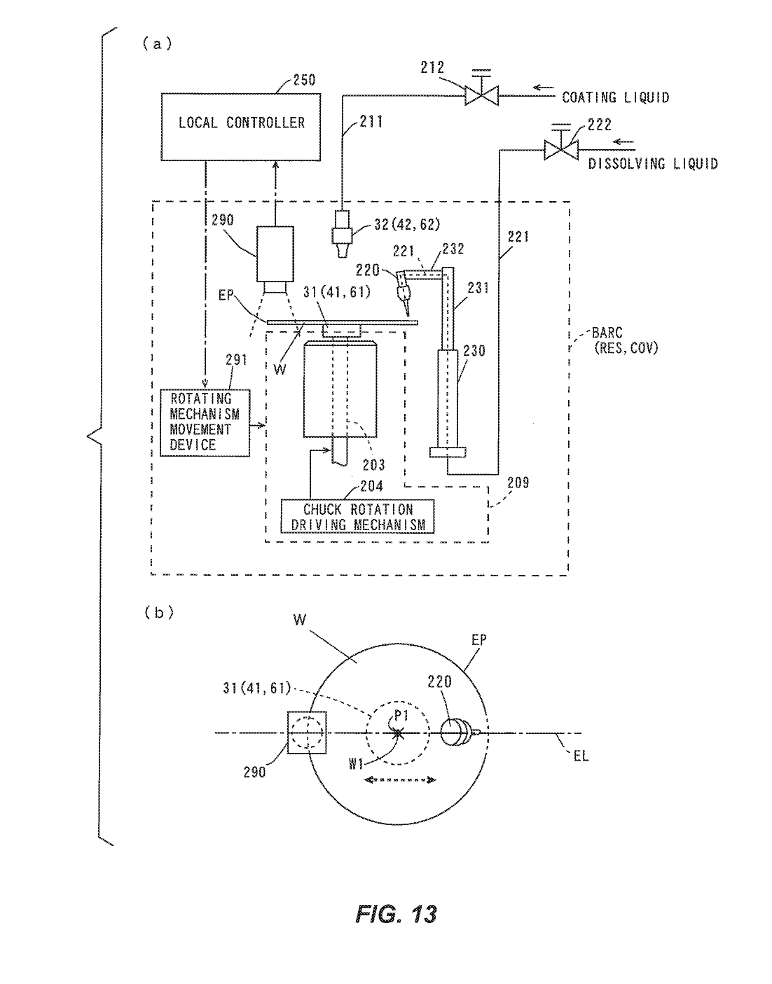

The coating units BARC, RES, and COV may further have the following configuration. The configuration of the coating unit BARC in this example will be described in detail with reference to the drawings. FIG. 13 is a diagram for explaining still another example of the configuration of the coating unit BARC. FIG. 13(a) is a side view showing still another example of the configuration of the coating unit BARC, and FIG. 13(b) is a top view of a part of the coating unit BARC shown in FIG. 13(a). The difference between the coating unit BARC shown in FIG. 13 and the coating unit BARC shown in FIG. 12 will be described.

Here, a spin chuck 31, a rotation shaft 203, and a chuck rotation driving mechanism 204 that constitute the coating unit BARC in this example are referred to as a substrate rotating mechanism 209. The coating unit BARC in this example is provided with a rotating mechanism movement device 291 for moving the substrate rotating mechanism 209 parallel to an eccentricity detection line EL. A local controller 250 rotates a substrate W once with the substrate rotating mechanism 209 fixed thereto. Thus, the relationship between a rotation angle from the reference angle of the spin chuck 31 and the amount of displacement of a peripheral edge EP of the substrate W on the eccentricity detection line EL is detected on the basis of an image given from a camera 290, and the detected relationship is stored.

The local controller 250 moves the substrate rotating mechanism 209 on the eccentricity detection line EL in real time (see an arrow in FIG. 13(b)) such that the relative position (distance) between the rotation center of the substrate W and the tip of the removal nozzle 220 is held on the basis of the stored relationship between the rotation angle and amount of displacement while the substrate W is being rotated.

The position where the removal nozzle 220 supplies the removal liquid to the substrate W can be kept constant from the peripheral edge EP of the substrate W by keeping the relative position (distance) between the center W1 of the substrate W and the tip of the removal nozzle 220 constant over the whole periphery of the substrate W during peripheral edge film removal processing. As a result, it is possible to accurately remove the film at the peripheral edge EP of the substrate W with high precision. Since the coating units RES and COV also have the same configuration as the coating unit BARC, the same effects can be obtained.

(3-f) Still Another Example Configuration of the Coating Unit

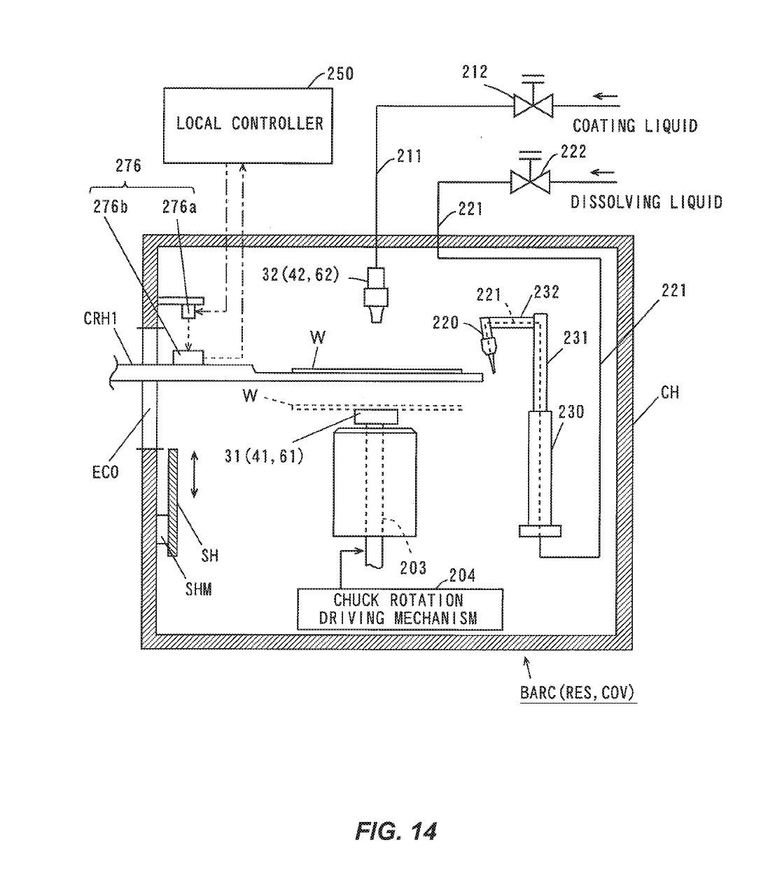

The coating units BARC, RES, and COV may further have the following configuration. FIG. 14 is a diagram for explaining still another example of the configuration of the coating unit BARC. FIG. 14(a) is a side view showing still another example of the configuration of the coating unit BARC, and FIG. 14(b) is a top view of a part of the coating unit BARC shown in FIG. 14(a). The difference between the coating unit BARC shown in FIG. 14 and the coating unit BARC shown in FIG. 4 will be described.

As shown in FIG. 14, in the coating unit BARC in this example, a spin chuck 31, a rotation shaft 203, a chuck rotation driving mechanism 204, a supply nozzle 32, and a removal nozzle 220 are arranged in a processing chamber CH. The arrangement of constituent elements within the processing chamber CH is approximately the same as that in the coating unit BARC shown in FIG. 4. The coating unit BARC in this example differs from the coating unit BARC shown in FIG. 4 in that it is not provided with guide arms 251 and 252.

An opening ECO for carrying a substrate W into and out of the coating unit BARC is formed on one side surface of the processing chamber CH. There are provided on the one side surface a shutter SH capable of opening and closing the opening ECO and a shutter driving device SHM for driving the shutter SH. The shutter SH opens the opening ECO so that the substrate W can be carried into and out of the coating unit BARC. The substrate W can be carried in and out with the hand CRH1 provided in the second central robot CR2 shown in FIG. 1.

Furthermore, a light projector 276a in a photoelectric sensor 276 is provided above the opening ECO on the one side surface of the processing chamber CH. A light receiver 276b in the photoelectric sensor 276 is provided in a predetermined area on an upper surface of the hand CRH1. The light projector 276a projects light in the vertical direction toward a bottom surface of the processing chamber CH, for example. The light projector 276a and the light receiver 276b in the photoelectric sensor 276 are connected to a local controller 250. The local controller 250 projects the light from the light projector 276a at the time of carrying the substrate W into the coating unit BARC. The light receiver 276b feeds, when it receives the light from the light projector 276a, a signal indicating that the light has been received (hereinafter referred to as a light receiving signal) to the local controller 250.

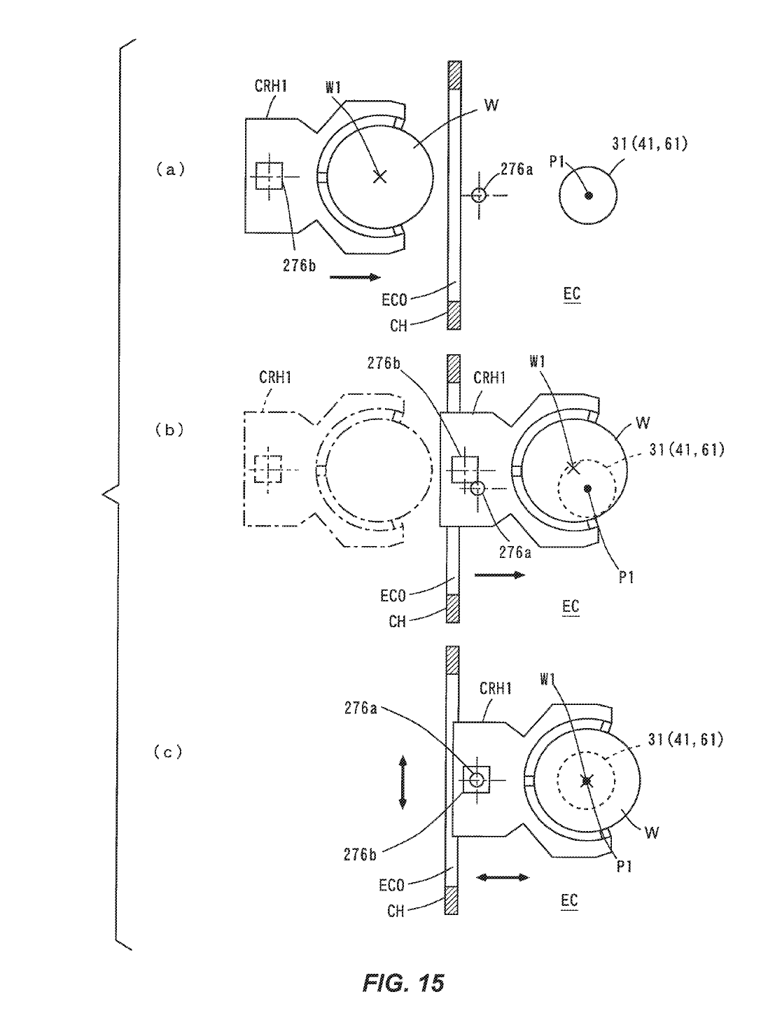

The local controller 250 controls the operation of each of the constituent elements in the coating unit BARC, and also controls the operation of the second central robot CR2 shown in FIG. 1. The operation of the hand CRH1 controlled by the local controller 250 will be described on the basis of FIG. 15.

FIG. 15 is a diagram for explaining the operation of the hand CRH1 shown in FIG. 14 when the substrate W is carried into the coating unit BARC. In FIG. 15, a part of the configuration of the hand CRH1 and the coating unit BARC (the light projector 276a and the spin chuck 31 in FIG. 14) is illustrated by a top view.

In FIG. 15(a), the substrate W held by the hand CRH1 is carried into the coating unit BARC, as indicated by an arrow. The positional relationship between the hand CRH1 and the spin chuck 31 is previously set.

However, the position of the hand CRH1 may, in some cases, be shifted from the previously set position. Thus, the substrate W carried into the coating unit BARC is placed on the spin chuck 31 with the center W1 of the substrate W shifted from the axis P1 of the spin chuck 31, as shown in FIG. 15(b). In this case, the light projected from the light projector 276a is not received by the light receiver 276b. Consequently, the light receiving signal is not fed to the local controller 250 from the light receiver 276b. Therefore, the local controller 250 moves the hand CRH1 within a horizontal plane until the light receiving signal is fed thereto from the light receiver 276b, as shown in FIG. 15(c). The local controller 250 stops, when the light receiving signal is fed thereto, the movement of the hand CRH1, and places the substrate W on the spin chuck 31.

Thus, the axis P1 of the spin chuck 31 and the center W1 of the substrate W coincide with each other. The position where the removal nozzle 220 supplies the removal liquid to the substrate W can be kept constant from the peripheral edge EP of the substrate W by keeping the relative position (distance) between the center W1 of the substrate W and the tip of the removal nozzle 220 constant over the whole periphery of the substrate W during peripheral edge film removal processing. As a result, it is possible to accurately remove the film at the peripheral edge EP of the substrate W with high precision. Since the coating units RES and COV also have the same configuration as the coating unit BARC, the same effects can be obtained.

The light receiving sensor 276 for matching the center W1 of the substrate W with the axis P1 of the spin chuck 31 can be also provided in the coating units BARC shown in FIGS. 4, 7, 9, 12, and 13. In this case, the local controller 250 can more sufficiently prevent the eccentricity of the substrate W by controlling the operation of the hand CRH1.

### (4) Effects in First Embodiment

(4-a) Effects of Peripheral Edge Film Removal Processing

In the present embodiment, after the anti-reflection film CVB, the resist film CVR, and the resist cover film CVT are formed on the surface of the substrate W, respectively, in the coating units BARC, RES, and COV, the film formed at the peripheral edge of the substrate W is removed by the peripheral edge film removal processing. Thus, no film exists at the peripheral edge of the substrate W, which prevents particles caused by a film due to mechanical contact between an arm of a robot and the substrate W from being generated when the substrate W is transported by the robot. As a result, processing defects in the substrate W due to the effect of the particles are prevented.

(4-b) Effects of Correction of Position of Substrate

The peripheral edge film removal processing for the substrate W is performed by discharging from the removal nozzle 220 opposed to the peripheral edge of the substrate W held and rotated by each of the spin chucks 31, 41, and 61 the removal liquid for dissolving the film formed on the surface of the substrate W.

In the present embodiment, the position of the substrate W is corrected before the peripheral edge film removal processing for the substrate W such that the center W1 of the substrate W coincides with the axis P1 of each of the spin chucks 31, 41, and 61 in the coating units BARC, RES, and COV. This prevents the substrate W from being eccentric from the axis P1 of each of the spin chucks 31, 41, and 61, i.e., the rotation center, which allows the film at the peripheral edge of the substrate W to be accurately removed with high precision.

(4-c) Removal Liquid used for Peripheral Edge Film Removal Processing

In the present embodiment, the removal liquid used for the peripheral edge film removal processing for the substrate W is not particularly limited, provided that it dissolves the anti-reflection film CVB, the resist film CVR, and the resist cover film CVT, respectively, in the coating unit BARC, RES, and COV. However, it is preferable that different removal liquids are used depending on the type of film to be dissolved. In this case, the film to be formed can be selectively dissolved and removed for each coating unit.

(4-d) Effects of Cleaning Processing of Substrate After Exposure Processing

The substrate W is subjected to the cleaning processing in the cleaning/drying processing group 80 in the cleaning/drying processing block 15 after being subjected to the exposure processing in the exposure device 17. In this case, even if the particles and the like in the atmosphere adhere to the substrate W to which the liquid adheres during the exposure processing, their deposits can be removed. This can prevent the substrate W from being contaminated. In the cleaning/drying processing group 80, the substrate W after the exposure processing is subjected to the drying processing. This prevents the liquid that has adhered to the substrate W during the exposure processing from dropping in the substrate processing apparatus 500. As a result, operational troubles such as abnormalities in an electric system in the substrate processing apparatus 500 can be prevented.

The particles and the like in the atmosphere are prevented from adhering to the substrate W after the exposure processing by subjecting the substrate W after the exposure processing to the drying processing, which can prevent the substrate W from being contaminated.

The substrate W to which the liquid adheres is prevented from being transported in the substrate processing apparatus 500, which can prevent the liquid that has adhered to the substrate W during the exposure processing from affecting the atmosphere in the substrate processing apparatus 500. This facilitates the adjustment of temperature and humidity in the substrate processing apparatus 500.

The liquid that has adhered to the substrate W during the exposure processing is prevented from adhering to the indexer robot IR and the second to eighth central robots CR2 to CR8, which prevents the liquid from adhering to the substrate W before the exposure processing. This prevents the particles and the like in the atmosphere from adhering to the substrate W before the exposure processing, thereby preventing the substrate W from being contaminated. As a result, it is possible to prevent degradation in resolution performance during the exposure processing and reliably prevent contamination in the exposure device 17. As a result, it is possible to reliably prevent processing defects in the substrate W.

A configuration for subjecting the substrate W after the exposure processing to the drying processing is not limited to that in the example of the substrate processing apparatus 500 shown in FIG. 1. Instead of providing the cleaning/drying processing block 15 between the resist cover film removal block 14 and the interface block 16, the cleaning/drying processing group 80 may be provided in the interface block 16 to subject the substrate W after the exposure processing to drying processing.

(4-e) Effects of Hand of Interface Transporting Mechanism

In the interface block 16, the hand H1 of the interface transporting mechanism IFR is used when the substrate W before the exposure processing is transported from the substrate platform PASS15 to the substrate carry-in section 17a in the exposure device 17 and when the substrate W after the cleaning and drying processing is transported from the cleaning/drying processing unit SD to the substrate platform PASS16, and the hand H2 of the interface transporting mechanism IFR is used when the substrate W after the exposure processing is transported from a substrate carry-out section 17b in the exposure device 17 to the cleaning/drying processing unit SD.

That is to say, the hand H1 is used for transporting the substrate W having no liquid adhering thereto, and the hand H2 is used for transporting the substrate W having a liquid adhering thereto. In this case, since the liquid that has adhered to the substrate W during the exposure processing is prevented from adhering to the hand H1, the liquid is prevented from adhering to the substrate W before the exposure processing. In addition, since the hand H2 is provided below the hand H1, the liquid can be prevented from adhering to the hand H1 and the substrate W held thereby even if the liquid drops from the hand H1 and the substrate W held thereby. This can reliably prevent the liquid from adhering to the substrate W before the exposure processing. As a result, the substrate W can be reliably prevented from being contaminated before the exposure processing.

(4-f) Effects of Removal Processing of Resist Cover Film

Before the substrate W is subjected to the development processing in the development processing block 12, the removal processing of the resist cover film is performed in the resist cover film removal block 14. In this case, the resist cover film is reliably removed before the development processing, so that the development processing can be reliably performed.

(4-g) Effects of Hands of Robot

In the second to sixth central robots CR2 to CR6 and the indexer robot IR, the upper hand is used for transporting the substrate W before the exposure processing, while the lower hand is used for transporting the substrate W after the exposure processing. This can reliably prevent the liquid from adhering to the substrate W before the exposure processing.

(4-h) As to Edge Exposure Unit

Although in the present embodiment, the resist film formed at the peripheral edge of the substrate W is removed by the peripheral edge film removal processing using the coating unit RES, the resist film formed at the peripheral edge of the substrate W may be removed by the exposure processing using the edge exposure unit EEW.

For example, in the substrate processing apparatus 500, the substrate W may, in some cases, be coated with only the anti-reflection film and the resist film. In this case, the resist film at the peripheral edge of the substrate W is exposed by the edge exposure unit EEW in place of the peripheral edge film removal processing by the coating unit RES. This allows the resist film at the peripheral edge of the substrate W to be removed.

The resist film at the peripheral edge of the substrate W is thus exposed, which allows the resist film to be removed with high precision.

A substrate processing apparatus according to a second embodiment has the same configuration and operation as the substrate processing apparatus 500 according to the first embodiment except for the following points.

(1) Configuration of Substrate Processing Apparatus

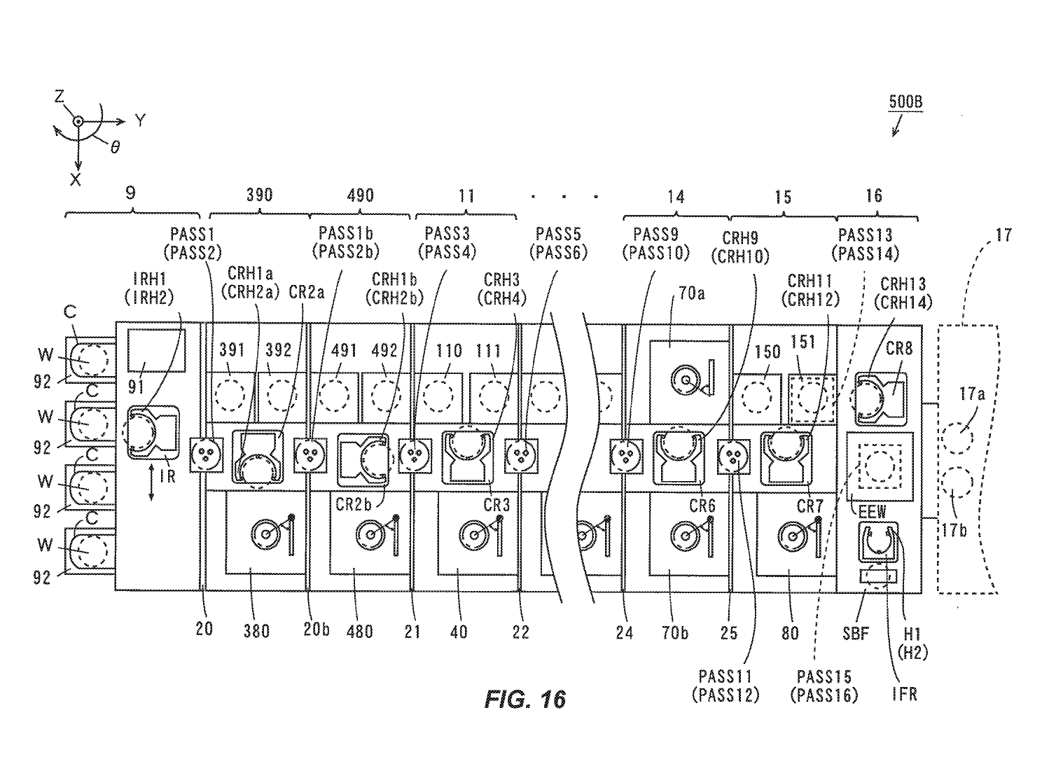

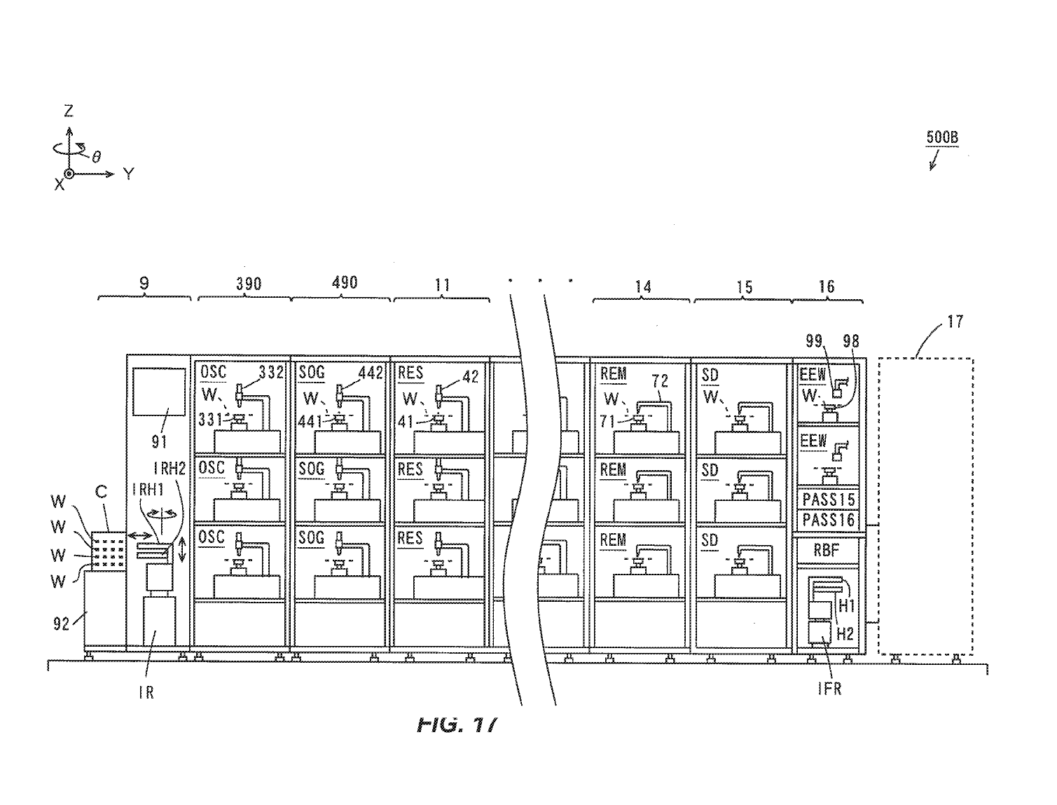

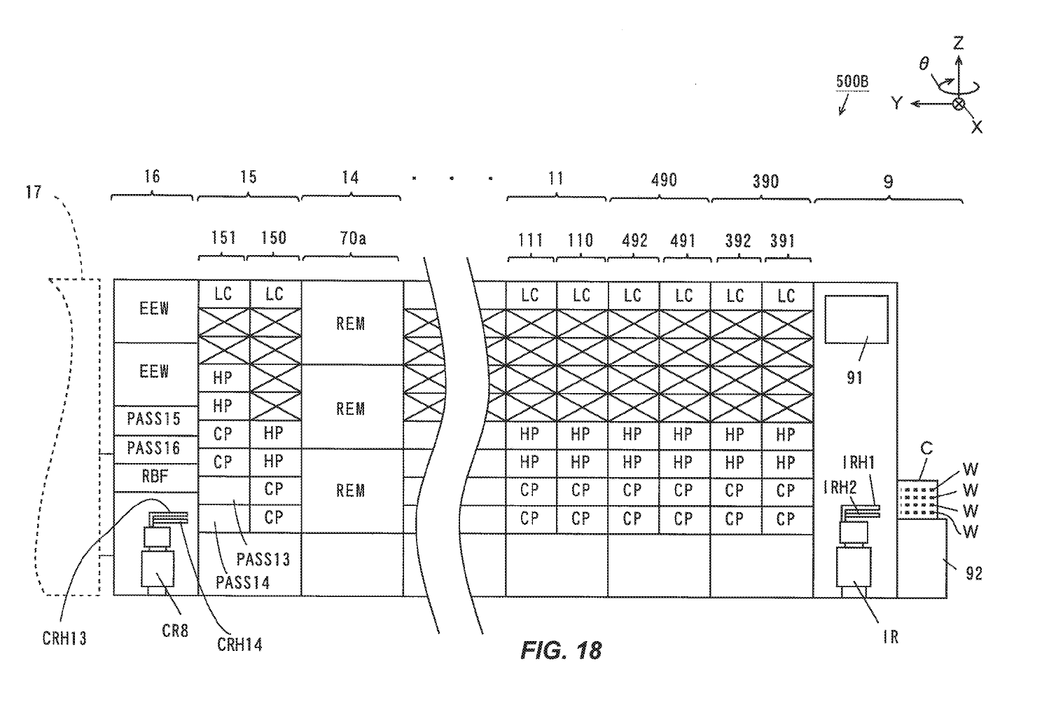

FIG. 16 is a schematic plan view of a substrate processing apparatus 500B according to the second embodiment, FIG. 17 is a side view of the substrate processing apparatus 500B shown in FIG. 16 as viewed from a +X direction, and FIG. 18 is a side view of the substrate processing apparatus 500B shown in FIG. 16 as viewed from a −X direction.

As shown in FIGS. 16 to 18, in the substrate processing apparatus 500B according to the present embodiment, an organic lower layer film processing block 390 and an oxide film processing block 490 are arranged side by side in this order adjacent to an indexer block 9 in place of the anti-reflection film processing block 10 in the substrate processing apparatus 500 according to the first invention (FIG. 1).

The organic lower layer film processing block 390 includes thermal processing groups 391 and 392 for organic lower layer film, a coating processing group 380 for organic lower layer film, and a ninth central robot CR2a. The coating processing group 380 is provided opposite to the thermal processing groups 391 and 392 with the ninth central robot CR2a interposed therebetween. The ninth central robot CR2a has hands CRH1a and CRH2a provided one above the other for receiving and transferring substrates W.

A partition wall 20 is provided between the indexer block 9 and the organic lower layer film processing block 390 for shielding an atmosphere, as in the first embodiment. The partition wall 20 is provided with substrate platforms PASS1 and PASS2 for transporting substrates W.

The oxide film processing block 490 includes thermal processing groups 491 and 492 for oxide film, a coating processing group 480 for oxide film, and a tenth central robot CR2b. The coating processing group 480 is provided opposite to the thermal processing groups 491 and 492 with the tenth central robot CR2b interposed therebetween. The tenth central robot CR2b has hands CRH1b and CRH2b provided one above the other for receiving and transferring the substrates W.

A partition wall 20b is provided between the organic lower layer film processing block 390 and the oxide film processing block 490 for shielding an atmosphere. The partition wall 20b has substrate platforms PASS1b and PASS2b provided in close proximity one above the other for receiving and transferring the substrates W between the organic lower layer film processing block 390 and the oxide film processing block 490. The upper substrate platform PASS1b is used in transporting the substrates W from the organic lower layer film processing block 390 to the oxide film processing block 490, and the lower substrate platform PASS2b is used in transporting the substrates W from the oxide film processing block 490 to the organic lower layer film processing block 390.

As shown in FIG. 17, the coating processing group 380 (see FIG. 16) in the organic lower layer film processing block 390 has a vertical stack of three coating units OSC. Each of the coating units OSC has the same configuration as each of the coating units BARC, RES, and COV described in the first embodiment, and comprises a removal nozzle (not shown) in addition to a spin chuck 331 and a supply nozzle 332. The removal nozzle corresponds to the removal nozzle 220 shown in FIGS. 4, 7, 9, and 12 to 14 in the first embodiment.

Thus, in the coating unit OSC, a coating liquid for an organic lower layer film is supplied to the substrate W held on the spin chuck 331 from the supply nozzle 332. This causes an organic lower layer film to be formed on a surface of the substrate W. Note that the organic lower layer film is formed on the substrate W as a base of an oxide film, described later. Thereafter, a removal liquid for dissolving and removing the organic lower layer film is discharged from a removal nozzle opposed to a peripheral edge of the organic lower layer film on the substrate W. This causes an annular region at the peripheral edge of the organic lower layer film formed on the substrate W to be removed.

As shown in FIG. 17, the coating processing group 480 (see FIG. 16) in the oxide film processing block 490 has a vertical stack of three coating units SOG. Each of the coating units SOG has the same configuration as each of the coating units BARC, RES, and COV described in the first embodiment, and comprises a removal nozzle (not shown) in addition to a spin chuck 441 and a supply nozzle 442. The removal nozzle corresponds to the removal nozzle 220 shown in FIGS. 4, 7, 9, and 12 to 14 in the first embodiment.

Thus, in the coating unit SOG, a coating liquid (e.g., liquid glass) for forming an oxide film is supplied to the substrate W held on the spin chuck 441 from the supply nozzle 442. This causes the oxide film to be formed on the substrate W. The oxide film is used for preventing, when a resist film formed on the substrate W is exposed and developed, pattern collapse of the formed resist film.

Thereafter, a removal liquid for dissolving and removing the oxide film is discharged from a removal nozzle opposed to a peripheral edge of the oxide film formed on the substrate W. This causes an annular region at the peripheral edge of the oxide film formed on the substrate W to be removed.

As shown in FIG. 18, in the organic lower layer film processing block 390, the thermal processing group 391 has a vertical stack of two heating units HP and two cooling units CP, and the thermal processing group 392 has a vertical stack of two heating units HP and two cooling units CP. Each of the thermal processing groups 391 and 392 has a local controller LC for controlling the respective temperatures of the cooling units CP and the heating units HP arranged in its uppermost part.

In the oxide film processing block 490, the thermal processing group 491 has a vertical stack of two heating units HP and two cooling units CP, and the thermal processing group 492 has a vertical stack of two heating units HP and two cooling units CP. Each of the thermal processing groups 491 and 492 has a local controller LC for controlling the respective temperatures of the cooling units CP and the heating units HP arranged in its uppermost part.

(2) Operation of Substrate Processing Apparatus

The ninth central robot CR2a in the organic lower layer film processing block 390 receives the substrate W placed on the substrate platform PASS1 by the indexer robot IR, and carries the substrate W into the coating processing group 380. In the coating processing group 380, each of the coating units OSC forms a coating of an organic lower layer film on the substrate W. An annular region at a peripheral edge of the organic lower layer film formed on the substrate W is removed, as described above.

Thereafter, the ninth central robot CR2a takes out the substrate W that has been subjected to the coating processing from the coating processing group 380 with the upper hand CRH1a, and carries the substrate W into the thermal processing group 391 or 392. Then, the ninth central robot CR2a takes out the thermally processed substrate W from the thermal processing group 391 or 392 with the upper hand CRH1a, and places the substrate W on the substrate platform PASS1b. The tenth central robot CR2b in the oxide film processing block 490 receives the substrate W placed on the substrate platform PASS1b, and carries the substrate W into the coating processing group 480.

In the coating processing group 480, each of the coating units SOG forms an oxide film on the substrate W on which the coating of the organic lower layer film has been formed. An annular region at a peripheral edge of the oxide film formed on the substrate W is removed, as described above. Thereafter, the tenth central robot CR2b takes out the substrate W that has been subjected to the coating processing from the coating processing group 480 with the upper hand CRH1b, and carries the substrate W into the thermal processing group 491 or 492. Then, the tenth central robot CR2b takes out the thermally processed substrate W from the thermal processing group 491 or 492 with the upper hand CRH1b, and places the substrate W on the substrate platform PASS3.

The substrate W placed on the substrate platform PASS3 is received by the third central robot CR3 in the resist film processing block 11, and is transported to the exposure device 17 through each of the blocks, as in the first embodiment. The substrate W that has been subjected to the exposure processing by the exposure device 17 is transported through each of the blocks, and is placed on the substrate platform PASS4, as in the first embodiment.

The substrate W placed on the substrate platform PASS4 is received with the lower hand CRH2b in the tenth central robot CR2b, and is placed on the substrate platform PASS2b. The substrate W placed on the substrate platform PASS2b is received with the lower hand CRH2a in the ninth central robot CR2a, and is placed on the substrate platform PASS2. Finally, the substrate W is accommodated in a carrier C by the indexer robot IR in the indexer block 9.

(3) Removal Region of Film Formed on Peripheral Edge of the Substrate W

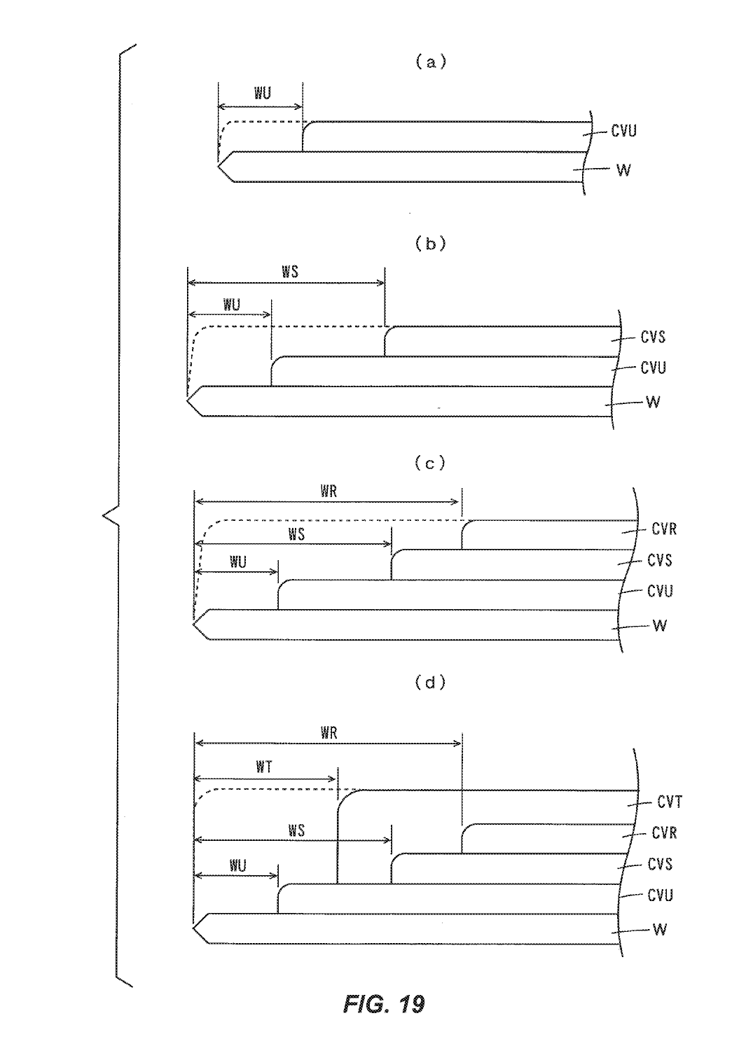

FIG. 19 is a diagram showing the procedure for forming an organic lower layer film, an oxide film, a resist film, and a resist cover film on a surface of a substrate W and a removal region of each of the films according to embodiments of the present invention.

In the present embodiment, in a coating unit OSC, an organic lower layer film CVU is formed on the surface of the substrate W, as shown in FIG. 19(a). A removal liquid is discharged into a peripheral edge of the organic lower layer film CVU from a removal nozzle, so that an annular region at the peripheral edge of the organic lower layer film CVU formed on the substrate W is removed. A removal region in the annular region of the organic lower layer film CVU is indicated by WU.

In a coating unit SOG, an oxide film CVS is then formed on the respective surfaces of the substrate W and the organic lower layer film CVU, as shown in FIG. 19(b). The removal liquid is discharged into a peripheral edge of the oxide film CVS from the removal nozzle, so that an annular region at the peripheral edge of the oxide film CVS formed on the substrate W is removed. A removal region in the annular region of the oxide film CVS is indicated by WS.

In a coating unit RES, a resist film CVR is then formed on the respective surfaces of the substrate W, the organic lower layer film CVU, and the oxide film CVS, as shown in FIG. 19(c). The removal liquid is discharged into a peripheral edge of the resist film CVR from the removal nozzle, so that an annular region at the peripheral edge of the resist film CVR formed on the substrate W is removed. A removal region in the annular region of the resist film CVR is indicated by WR.

Thereafter, in the coating unit COV, a resist cover film CVT is then formed on the respective surfaces of the substrate W, the organic lower layer film CVU, the oxide film CVS, and the resist film CVR, as shown in FIG. 19(d). The removal liquid is discharged into a peripheral edge of the resist cover film CVT from the removal nozzle, so that an annular region at the peripheral edge of the resist cover film CVT formed on the substrate W is removed. A removal region in the annular region of the resist cover film CVT is indicated by WT.

In this case, the removal region WU of the organic lower layer film CVU, the removal region WT of the resist cover film CVT, the removal region WS of the oxide film CVS, and the removal region WR of the resist film CVR are set so as to increase in this order. This causes the following effects to be obtained.

The organic lower layer film CVU formed on the substrate W is more difficult to strip from the substrate W, as compared with the resist film CVR and the resist cover film CVT. Consequently, the removal region WU of the organic lower layer film CVU is made smaller than the respective removal regions WR and WT of the resist film CVR and the resist cover film CVT, so that the stripping of the films formed on the substrate W is reduced. Furthermore, the oxide film CVS can be reliably formed on the organic lower layer film CVU by making the removal region WU of the organic lower layer film CVU smaller than the removal region WS of the oxide film CVS.

The surface of the resist film CVR can be completely covered with the resist cover film CVT by making the removal region WR of the resist film CVR larger than the removal region WT of the resist cover film CVT. This can prevent the resist film CVR from being eluded into the liquid during the exposure processing.

In the present embodiment, the position of the substrate W is corrected such that the center of the substrate W coincides with the axis of each of the spin chucks 331 and 441 before peripheral edge film removal processing for the substrate W. The peripheral edge film removal processing for the substrate W is performed using a needle-shaped nozzle portion having a small diameter. This allows the film at the peripheral edge of the substrate W to be accurately removed with high precision during the peripheral edge film removal processing.

In the following paragraphs, non-limiting examples of correspondences between various elements recited in the claims below and those described above with respect to various preferred embodiments of the present invention are explained.

In the first and second embodiments described above, the anti-reflection film processing block 10, the resist film processing block 11, the development processing block 12, the resist cover film processing block 13, the resist cover removal block 14, the cleaning/drying processing block 15, the organic lower layer film processing block 390, and the oxide film processing block 490 are examples of a processing section, and the interface block 16 is an example of an interface.

The coating units BARC, RES, COV, OSC, and SOG are examples of a film formation unit, the coating unit BARC in the anti-reflection film processing block 10, the coating unit OSC in the organic lower layer film processing block 390, and the coating unit SOG in the oxide film processing block 490 are examples of a first film formation unit, the coating unit RES in the coating processing group 40 for resist film is an example of a second film formation unit, and the coating unit COV in the coating processing group 60 for resist cover film is an example of a third film formation unit.

Furthermore, the annular region at the peripheral edge of the anti-reflection film CVB, the annular region at the peripheral edge of the organic lower layer film CVU, and the annular region at the peripheral edge of the oxide film CVS are examples of a first annular region, the annular region at the peripheral edge of the resist film CVR is an example of a second annular region, and the annular region at the peripheral edge of the resist cover film CVT is an example of a third annular region.

Furthermore, the spin chucks 31, 41, 61, 331, and 441 are examples of a substrate holding device, the chuck rotation driving mechanism 204 is an example of a rotation driving device, the supply nozzles 32, 42, 62, 332, and 442 are examples of a film formation device, the removal nozzle 220 is an example of a removal device, the substrate rotating mechanism 209, the removal nozzle moving mechanism 239, the local controller 250, the guide arms 251 and 252, the supporting members 253 and 254, the arm moving mechanisms 255 and 256, the correction pin 261, the pin driving device 262, the pin holder 271, the support pin 271P, the lifting shaft 272, the pin driving device 273, the rotating mechanism movement device 291, the hands CRH1, CRH1a, CRH1b, CRH3, and CRH7 are examples of a position correction device.

The guide arms 251 and 252 and the support pin 271P are examples of an abutting member, the correction pin 261 is an example of a supporting member, the eccentric sensor 263 is an example of a substrate position detector, the local controller 250 is an example of a control device, the interface transporting mechanism IFR is an example of a transport device, and the hands H1 and H2 are respective examples of first and second holders.

Furthermore, the pin driving device 273 is an example of a lifting device, the camera 290 is an example of an edge detector, the removal nozzle moving mechanism 239 is an example of a removal device moving mechanism, the rotating mechanism movement device 291 is an example of a holding device moving mechanism, the photoelectric sensor 276 is an example of a carry-in position detector, and the local controller 250 is an example of a position adjustment device.

As each of constituent elements in the claims, various other elements having the configurations or the functions described in the claims can be also used.

While preferred embodiments of the present invention have been described above, it is to be understood that variations and modifications will be apparent to those skilled in the art without departing the scope and spirit of the present invention. The scope of the present invention, therefore, is to be determined solely by the following claims.

What is claimed is:

1. A substrate processing method for forming a plurality of films on an upper surface of a substrate before exposure processing by a liquid immersion method, comprising the steps of:
forming a first film on the upper surface of the substrate in a first film formation unit;
supplying a first removal liquid to a peripheral edge of said first film from a first removal nozzle in said first film formation unit, to remove a first annular region at the peripheral edge;
correcting a relative positional relationship between the substrate and said first removal nozzle so that said first annular region at the peripheral edge of said first film is removed in a predetermined first constant width in said first film formation unit before the removal of said first film;
forming a second film so as to cover the first film from which said first annular region is removed in a second film formation unit;
supplying a second removal liquid to a peripheral edge of said second film from a second removal nozzle in said second film formation unit, to remove a second annular region at the peripheral edge;
correcting a relative positional relationship between the substrate and said second removal nozzle so that said second annular region at the peripheral edge of said second film is removed in a predetermined second constant width in said second film formation unit before the removal of said second film; and
carrying the substrate into each of said first and second film formation units by a carry-in device,
wherein the step of removing said first annular region includes the steps of:
holding the substrate substantially horizontally;
rotating the held substrate around a first axis perpendicular to the substrate; and
supplying said first removal liquid from said first removal nozzle to the peripheral edge of the first film formed on the rotated substrate, to remove said first annular region,
the step of removing said second annular region includes the steps of:
holding the substrate substantially horizontally;
rotating the held substrate around a second axis perpendicular to the substrate; and
supplying said second removal liquid from said second removal nozzle to the peripheral edge of the second film formed on the rotated substrate, to remove said second annular region,
the step of correcting the relative positional relationship between the substrate and said first removal nozzle includes the steps of:
detecting a position of said carry-in device when the substrate is carried into said first film formation unit by said carry-in device; and
adjusting the position of said carry-in device on the basis of the detected position, and
the step of correcting the relative positional relationship between the substrate and said second removal nozzle includes the steps of:
detecting the position of said carry-in device when the substrate is carried into said second film formation unit by said carry-in device; and
adjusting the position of said carry-in device on the basis of the detected position.

2. The substrate processing method according to claim 1, wherein said first width is smaller than said second width.

3. The substrate processing method according to claim 1, wherein the step of correcting the relative positional relationship between the substrate and said first removal nozzle includes the step of adjusting the position of said carry-in device so that a center of the substrate carried in by said carry-in device is positioned on the first axis, and
the step of correcting the relative positional relationship between the substrate and said second removal nozzle includes the step of adjusting the position of said carry-in device so that the center of the substrate carried in by said carry-in device is positioned on the second axis.

4. The substrate processing method according to claim 1, further comprising:
forming a third film so as to cover the second film from which said second annular region is removed in a third film formation unit;
supplying a third removal liquid to a peripheral edge of said third film from a third removal nozzle in said third film formation unit, to remove a third annular region at the peripheral edge;
correcting a relative positional relationship between the substrate and said third removal nozzle so that said third annular region at the peripheral edge of said third film is removed in a predetermined third constant width in said third film formation unit before the removal of said third film; and
carrying the substrate into said third film formation unit by said carry-in device,
wherein the step of removing said third annular region includes the steps of:
holding the substrate substantially horizontally;
rotating the held substrate around a third axis perpendicular to the substrate; and
supplying said third removal liquid from said third removal nozzle to the peripheral edge of the third film formed on the rotated substrate, to remove said third annular region, and
the step of correcting the relative positional relationship between the substrate and said third removal nozzle includes the steps of:
detecting the position of said carry-in device when the substrate is carried into said third film formation unit by said carry-in device; and
adjusting the position of said carry-in device on the basis of the detected position.

5. The substrate processing method according to claim 4, wherein said first width is smaller than said third width, and said third width is smaller than said second width.

6. The substrate processing method according to claim 4, wherein the step of correcting the relative positional relationship between the substrate and said first removal nozzle includes the step of adjusting the position of said carry-in device so that the center of the substrate carried in by said carry-in device is positioned on the first axis,
the step of correcting the relative positional relationship between the substrate and said second removal nozzle includes the step of adjusting the position of said carry-in device so that the center of the substrate carried in by said carry-in device is positioned on the second axis, and
the step of correcting the relative positional relationship between the substrate and said third removal nozzle includes the step of adjusting the position of said carry-in device so that the center of the substrate carried in by said carry-in device is positioned on the third axis.

7. The substrate processing method according to claim 4, further comprising:
forming a fourth film before the formation of the second film so as to cover the first film from which said first annular region is removed in a fourth film formation unit;
supplying a fourth removal liquid to a peripheral edge of said fourth film from a fourth removal nozzle in said fourth film formation unit, to remove a fourth annular region at the peripheral edge;
correcting a relative positional relationship between the substrate and said fourth removal nozzle so that said fourth annular region at the peripheral edge of said fourth film is removed in a predetermined fourth constant width in said fourth film formation unit before the removal of said fourth film; and
carrying the substrate into said fourth film formation unit by said carry-in device,
wherein the step of removing said fourth annular region includes the steps of:
holding the substrate substantially horizontally;
rotating the held substrate around a fourth axis perpendicular to the substrate; and
supplying said fourth removal liquid from said fourth removal nozzle to the peripheral edge of the fourth film formed on the rotated substrate, to remove said fourth annular region, and
the step of correcting the relative positional relationship between the substrate and said fourth removal nozzle includes the steps of:
detecting the position of said carry-in device when the substrate is carried into said fourth film formation unit by said carry-in device; and
adjusting the position of said carry-in device on the basis of the detected position.

8. The substrate processing method according to claim 7, wherein said first width is smaller than said third width, said third width is smaller than said fourth width, and said fourth width is smaller than said second width.

9. The substrate processing method according to claim 7, wherein the step of correcting the relative positional relationship between the substrate and said first removal nozzle includes the step of adjusting the position of said carry-in device so that the center of the substrate carried in by said carry-in device is positioned on the first axis,
the step of correcting the relative positional relationship between the substrate and said second removal nozzle includes the step of adjusting the position of said carry-in device so that the center of the substrate carried in by said carry-in device is positioned on the second axis,
the step of correcting the relative positional relationship between the substrate and said third removal nozzle includes the step of adjusting the position of said carry-in device so that the center of the substrate carried in by said carry-in device is positioned on the third axis, and
the step of correcting the relative positional relationship between the substrate and said fourth removal nozzle includes the step of adjusting the position of said carry-in device so that the center of the substrate carried in by said carry-in device is positioned on the fourth axis.
